(19) United States
(12) Patent Application Publication
(10) Pub. No.: US 2024/0292718 A1
(43) Pub. Date: Aug. 29, 2024

(54) DISPLAY PANEL AND DISPLAY DEVICE INCLUDING THE SAME

(71) Applicants: Chengdu BOE Optoelectronics Technology Co., Ltd., Chengdu, Sichuan (CN); BOE Technology Group Co., Ltd., Beijing (CN)

(72) Inventors: Qiyun Wang, Beijing (CN); Cheng Zeng, Beijing (CN); Zhenye Wei, Beijing (CN); Guangri Yu, Beijing (CN); Li Chen, Beijing (CN); Zhen Sun, Beijing (CN); Lulin MA, Beijing (CN); Hongwei Zhang, Beijing (CN); Xiongyi Luo, Beijing (CN)

(73) Assignees: Chengdu BOE Optoelectronics Technology Co., Ltd., Chengdu, Sichuan (CN); BOE Technology Group Co., Ltd., Beijing (CN)

(21) Appl. No.: 18/023,074

(22) PCT Filed: Mar. 25, 2022
(86) PCT No.: PCT/CN2022/083162

§ 371 Date: Feb. 24, 2023

(51) Int. Cl. H10K 59/80

(52) U.S. Cl. CPC H10K 59/879

(57) ABSTRACT

A display panel, including a light-emitting base plate including light-emitting devices arranged in an array; first light-extracting layers, located on light-outlet sides of at least a part of the light-emitting devices, each including prisms extending along a first direction and arranged along a second direction; and second light-extracting layers, located on the light-outlet sides of the light-emitting devices, and on a side of the first light-extracting layers away from the light-emitting base plate, each including convex lenses arranged in an array, wherein an orthographic projection of the first light-extracting layer on the light-emitting base plate is within an orthographic projection of the second light-extracting layer on the light-emitting base plate, a maximum size of the prism along the second direction is less than or equal to a maximum size of the convex lens along the second direction, and the first direction intersects the second direction.

### FIELD

The present application relates to the field of display technology, in particular to a display panel and a display device including the display panel.

### BACKGROUND

An OLED, known as an organic light-emitting diode as well, excites electrons in light-emitting material by means of electric injection, and gives out light through the electrons in the light-emitting material returning to a ground state. Compared with other display devices, the OLED has a higher contrast, a wider color gamut, and a shorter response time, and may realize characteristics such as ultra-thin flexibility, etc. However, light-outlet efficiency of OLED display products is low; and there is a significant problem of color deviation of large view angle.

### SUMMARY

Embodiments of the application adopts the following technical solutions.

In a first aspect of the disclosure, an embodiment of the present application provides a display panel, including:
a light-emitting base plate, including a plurality of light-emitting devices arranged in an array;
first light-extracting layers, located on light-outlet sides of at least a part of the light-emitting devices, wherein each of the first light-extracting layers includes a plurality of prisms extending along a first direction and arranged along a second direction; and
second light-extracting layers, located on the light-outlet sides of the light-emitting devices, and on a side of the first light-extracting layers away from the light-emitting base plate, wherein each of the second light-extracting layers includes a plurality of convex lenses arranged in an array,
wherein an orthographic projection of each of the first light-extracting layers on the light-emitting base plate is within an orthographic projection of a corresponding one of the second light-extracting layers on the light-emitting base plate, a maximum size of the prism along the second direction is less than or equal to a maximum size of the convex lens along the second direction, and the first direction intersects the second direction.

In some embodiments of the disclosure, along the second direction, a spacing size between every two adjacent ones of the prisms is greater than or equal to a spacing size between every two adjacent ones of the convex lenses.

In some embodiments of the disclosure, for the first light-extracting layer and the second light-extracting layer located on the light-outlet side of a same one of the light-emitting devices, an outer contour of the orthographic projection of the first light-extracting layer on the light-emitting base plate is within an outer contour of the orthographic projection of the second light-extracting layer on the light-emitting base plate.

In some embodiments of the disclosure, for the first light-extracting layer and the second light-extracting layer located on the light-outlet side of the same one of the light-emitting devices, the outer contour of the orthographic projection of the first light-extracting layer on the light-emitting base plate is within an outer contour of an orthographic projection of a first graph on the light-emitting base plate, and
the first graph is a closed graph formed by successively connecting focuses of the convex lenses of an outermost lap in the second light-extracting layer.

In some embodiments of the disclosure, the display panel further includes: color-resistance layers, wherein the color-resistance layers are located on a side of the second light-extracting layers away from the light-emitting base plate, and
the outer contour of the orthographic projection of the second light-extracting layer on the light-emitting base plate is located within an outer contour of an orthographic projection of the corresponding color-resistance layer on the light-emitting base plate.

In some embodiments of the disclosure, the display panel further includes: color-resistance layers, wherein the color-resistance layers are located on a side of the second light-extracting layers away from the light-emitting base plate, and
the orthographic projection of the second light-extracting layer on the light-emitting base plate partially overlaps with an orthographic projection of the corresponding color-resistance layer on the light-emitting base plate, and the outer contour of the orthographic projection of the first graph on the light-emitting base plate is within an outer contour of the orthographic projection of the color-resistance layer on the light-emitting base plate.

In some embodiments of the disclosure, the display panel further includes: a substrate, color-converting layers, and color-resistance layer, wherein the color-converting layers are located between a part of the light-emitting devices and the first light-extracting layers, and the color-resistance layers are located on a side of the second light-extracting layers away from the light-emitting base plate, and
wherein orthographic projections of the color-converting layers on the substrate cover at least a part of orthographic projections of the light-emitting devices on the substrate, and orthographic projections of the color-resistance layers on the substrate overlap with orthographic projections of the color-converting layer on the substrate.

In some embodiments of the disclosure, the light-emitting devices include first light-emitting devices, second light-emitting devices, and third light-emitting devices, the color-converting layers include first color-converting patterns on a light-outlet side of the first light-emitting devices and second color-converting patterns on a light-outlet side of the second light-emitting devices, the display panel further includes light-transmitting patterns located on a light-outlet side of the third light-emitting devices, and the light-transmitting patterns are arranged on a same layer as the color-converting layers, and
wherein, light-emitting colors of the first light-emitting device, the second light-emitting device and the third light-emitting device are the same, and color of light converted by the first color-converting pattern, color of light converted by the second color-converting pattern and color of light passing the light-transmitting pattern are different from each other.

In some embodiments of the disclosure, the first color-converting pattern and the second color-converting pattern respectively include quantum dots, and the light-transmitting pattern includes scattering particles.

In some embodiments of the disclosure, orthographic projections of a row of the convex lenses on the light-emitting base plate overlap with an orthographic projection of at least one of the prisms on the light-emitting base plate.

In some embodiments of the disclosure, along the second direction, a number of the prisms included in the first light-extracting layer is greater than or equal to a number of the convex lenses included in the second light-extracting layer.

In some embodiments of the disclosure, the first light-extracting layer includes first prisms and second prisms that are spaced, and
maximum sizes of the first prism and the second prism along the second direction are the same, and a height of the first prism in a direction perpendicular to the light-emitting base plate is greater than or equal to a height of the second prism in the direction perpendicular to the light-emitting base plate.

In some embodiments of the disclosure, the second light-extracting layer includes first convex lenses and second convex lenses that are spaced along the second direction, and
maximum sizes of the first convex lens and the second convex lens along the second direction are the same, and a height of the first convex lens in the direction perpendicular to the light-emitting base plate is greater than or equal to a height of the second convex lens in the direction perpendicular to the light-emitting base plate.

In some embodiments of the disclosure, along the second direction, the number of prisms included in the first light-extracting layer is equal to the number of convex lenses included in the second light-extracting layer, and
an orthographic projection of the first convex lens on the light-emitting base plate overlaps with an orthographic projection of the first prism on the light-emitting base plate, and an orthographic projection of the second convex lens on the light-emitting base plate overlaps with an orthographic projection of the second prism on the light-emitting base plate.

In some embodiments of the disclosure, along the second direction, the number of prisms included in the first light-extracting layer is greater than the number of convex lenses included in the second light-extracting layer.

In some embodiments of the disclosure, the orthographic projections of the row of convex lenses on the light-emitting base plate overlap with the orthographic projections of two of the prisms on the light-emitting base plate, and an orthographic projection of a connecting line of focus of the row of convex lenses on the light-emitting base plate is located between the orthographic projections of the two of prisms on the light-emitting base plate.

In some embodiments of the disclosure, the first light-extracting layer includes a middle region and an edge region on both sides of the middle region, wherein heights of the respective prisms in the first light-extracting layer in a direction perpendicular to the light-emitting base plate gradually decrease along a third direction, and
the third direction is a direction from the edge region to the middle region, or the third direction is a direction from the middle region to the edge region.

In some embodiments of the disclosure, the second light-extracting layer includes a center region and a peripheral region surrounding the center region, wherein heights of the respective convex lenses in the second light-extracting layer in a direction perpendicular to the light-emitting base plate gradually decrease along a fourth direction, and
the fourth direction is a direction from the peripheral region to the center region, or the fourth direction is a direction from the center region to the peripheral region.

In some embodiments of the disclosure, the first light-extracting layer includes a middle region and an edge region on both sides of the middle region, wherein heights of the respective prisms in the first light-extracting layer in a direction perpendicular to the light-emitting base plate gradually decrease along a direction from the middle region to the edge region, and
the second light-extracting layer includes a center region and a peripheral region surrounding the center region, wherein heights of the respective convex lenses in the second light-extracting layer in a direction perpendicular to the light-emitting base plate gradually increase along a direction from the center region to the peripheral region.

In some embodiments of the disclosure, the display panel further includes a first cover layer and a second cover layer, wherein the first cover layer covers at least the first light-extracting layer, and the second cover layer covers the second light-extracting layer, and
wherein a refractive index of the first light-extracting layer is greater than that of the first cover layer, and a refractive index of the second light-extracting layer is greater than that of the second cover layer.

In some embodiments of the disclosure, the refractive index of the first cover layer is greater than that of the second light-extracting layer.

In a second aspect of the disclosure, an embodiment of the present application provides a display device, including the display panel as described above.

The above description is only an overview of the technical solutions of the application. In order to better understand the technical means of the application, so as to implement the technical means according to the contents of the specification, and in order to make the above and other purposes, features and advantages of the application more distinct and understandable, specific implementations of the application are listed below.

### BRIEF DESCRIPTION OF THE DRAWINGS

In order to more clearly illustrate technical solutions in embodiments of the disclosure or in related technology, the followings will briefly introduce drawings needed to be used in illustrating the embodiments or the related technology. Apparently, the drawings in the following description are only some embodiments of the disclosure. For those ordinary skilled in the field, they may further obtain other drawings according to the provided drawings without paying creative labor.

FIG. 1 is a schematic view showing a structural of a display panel provided by an embodiment of the present application.

FIG. 2 is a schematic view showing a structural of a first light-extracting layer provided by an embodiment of the present application.

FIG. 3 is a schematic view showing a structural of a second light-extracting layer provided by an embodiment of the present application.

FIG. 6 is a schematic view showing a projection relationship between the first light-extracting layer and the second light-extracting layer provided by an embodiment of the present application.

FIG. 4, FIG. 5, FIG. 7-FIG. 20 are schematic views showing structures of sixteen display panels further provided by embodiments of the present application.

FIG. 21 is a schematic view showing luminance-decay (L-Decay) curves of a display panel provided by an embodiment of the present application, before and after setting the first light-extracting layer thereon.

FIG. 22 is a schematic view showing luminance-decay curves of a display panel provided by an embodiment of the present application, before and after setting the first light-extracting layer and the second light-extracting layer thereon.

FIG. 23 is a schematic view showing luminance-decay curves of different colors of lights emitted from color-converting patterns and a light-transmitting pattern, before setting the first light-extracting layer and the second light-extracting layer, in related technology.

FIG. 24 is a schematic view showing luminance-decay curves of different colors of lights emitted from the color-converting patterns and the light-transmitting pattern, after setting the first light-extracting layer and the second light-extracting layer, provided by an embodiment of the present application.

FIG. 25 is a schematic view showing a track of white point coordinates of a display panel, changed in a color gamut diagram along with view angles, before setting the first light-extracting layer and the second light-extracting layer, and after setting the first light-extracting layer and the second light-extracting layer thereon.

### DETAILED DESCRIPTION OF THE EMBODIMENTS

The followings will describe the technical solutions in the embodiments of the application clearly and completely in combination with the drawings in the embodiments of the application. Apparently, the described embodiments are only a part of the embodiments of the application, not all of the embodiments of the application. Based on the embodiments in the application, all other embodiments obtained by the ordinary skilled in the art without doing creative work belong to the scope of protection in the application.

In the drawings, thicknesses of areas and layers may be exaggerated for clarity. The same reference numerals in the drawings represent the same or similar structures, so the detailed description thereof will be omitted. In addition, the drawings are only schematic illustrations of the application, and are not necessarily drawn to scale.

Unless otherwise required by the context, in the entire specification and claims, the term “including” is interpreted as open and inclusive, which means “including, but not limited to”. In the description of the specification, the terms “one embodiment”, “some embodiments”, “an exemplary embodiment”, “an example”, “a specific example” or “some examples” are intended to indicate that specific features, structures, materials or characteristics related to the embodiment or example are included in at least one embodiment or example of the application. The illustrative representation of the above terms does not necessarily refer to the same embodiment or example. In addition, the above specific features, structures, materials or characteristics may be included in any one or more embodiments or examples in any appropriate manner.

In the embodiments of the present application, the words such as “first”, “second”, etc., are used to describe the same or similar items with basically the same function and action, only for the purpose of clearly describing the technical solution of the embodiments of the present application, and shall not be understood as indicating or implying relative importance or implying quantity of an indicated technical feature.

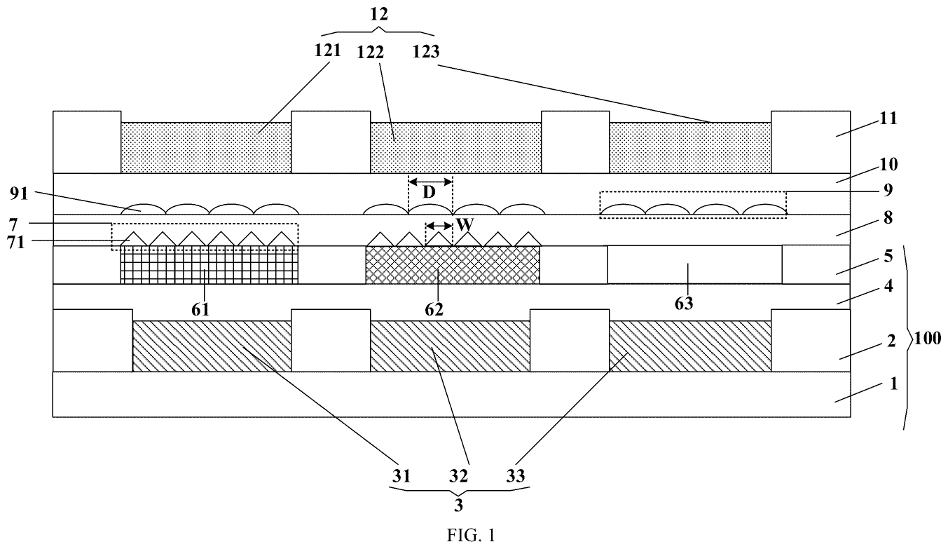

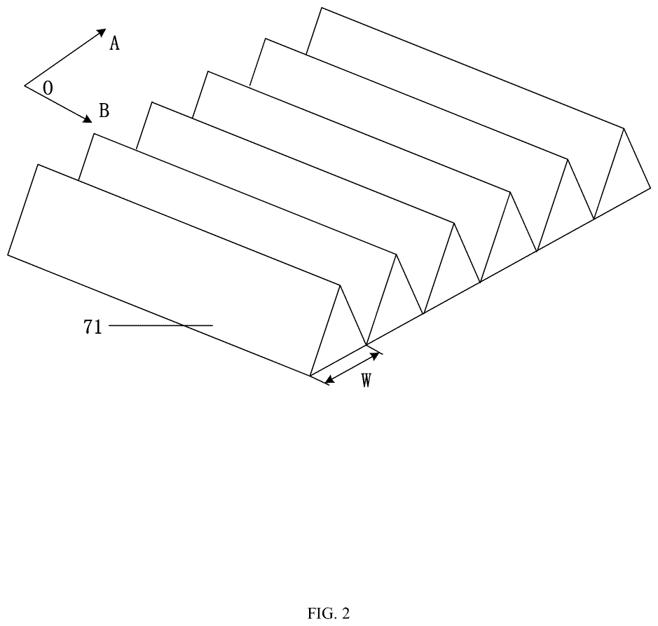

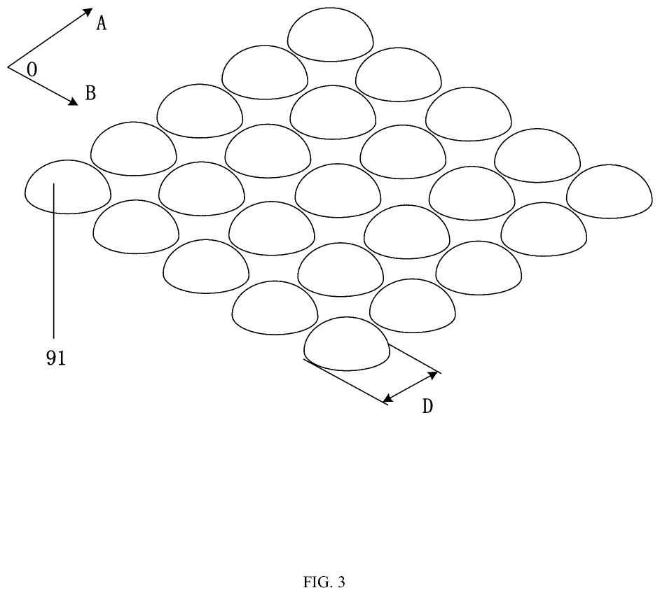

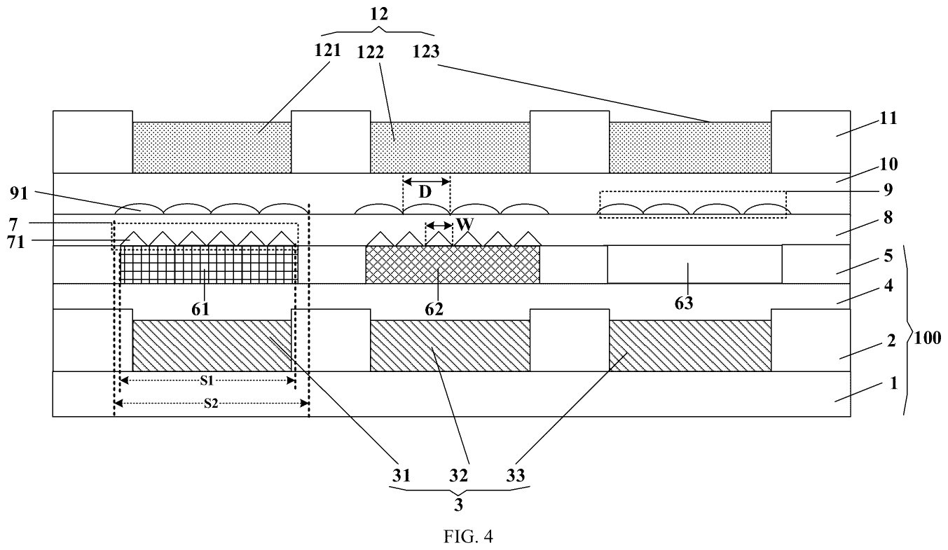

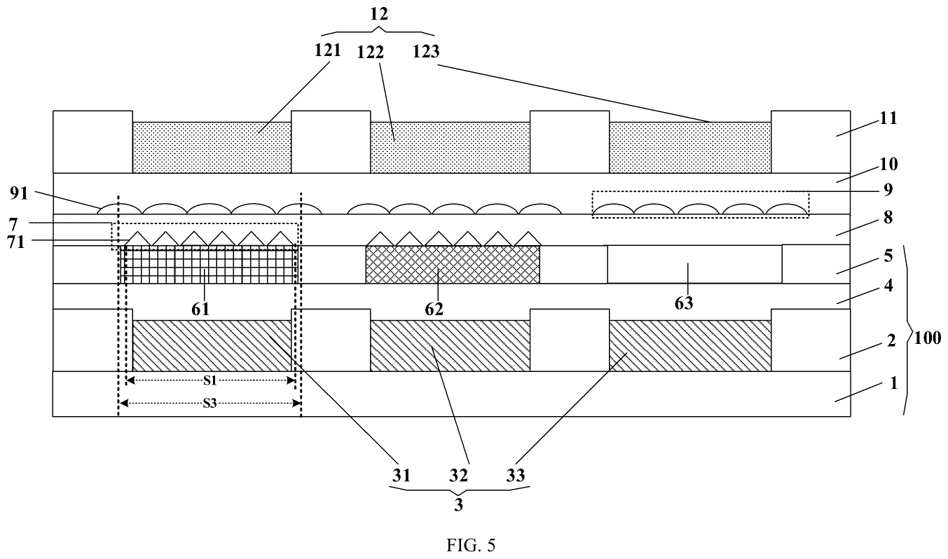

An embodiment of the application provides a display panel, as shown in a combination of FIG. 1, FIG. 2 and FIG. 3, including:
a light-emitting base plate 100, including a plurality of light-emitting devices 3 arranged in an array;
a plurality of first light-extracting layers 7, located on light-outlet sides of at least a part of the light-emitting devices 3, wherein each of the plurality of first light-extracting layers 7 includes a plurality of prisms 71 extending along a first direction OB and arranged along a second direction OA; and
a plurality of second light-extracting layers 9, located on the light-outlet sides of the light-emitting devices 3, and on a side of the first light-extracting layers 7 away from the light-emitting base plate 100, wherein each of the plurality of second light-extracting layers 9 includes a plurality of convex lenses 91 arranged in an array,
wherein an orthographic projection of each of the plurality of first light-extracting layers 7 on the light-emitting base plate 100 is within an orthographic projection of a corresponding one of the plurality of second light-extracting layers 9 on the light-emitting base plate 100, a maximum size W of the prism 71 along the second direction OA is less than or equal to a maximum size D of the convex lens 9 along the second direction OA, and the first direction OB intersects the second direction OA.

A specific structure of the above light-emitting base plate 100 is not limited here, which may be specifically determined according to an actual situation.

A meaning that the above plurality of first light-extracting layers 7 are located on the light-outlet sides of at least the part of the light-emitting devices 3 is that the first light-extracting layers 7 are arranged on the light-outlet sides of a part of the light-emitting devices 3, or the first light-extracting layers 7 are arranged on the light-outlet sides of all of the light-emitting devices 3.

Among them, the light-emitting devices may include first light-emitting devices 31, second light-emitting devices 32 and third light-emitting devices 33. In some embodiments, light-emitting colors of the first light-emitting devices 31, the second light-emitting devices 32 and the third light-emitting devices 33 may be the same. In some embodiments, the light-emitting colors of the first light-emitting devices 31, the second light-emitting devices 32 and the third light-emitting devices 33 may be different from each other. The embodiment of the present application is illustrated by taking that the light-emitting colors of the first light-emitting devices 31, the second light-emitting devices 32 and the third light-emitting devices 33 may be the same, as an example.

That the first light-extracting layers 7 are set on the light-outlet sides of the part of the light-emitting devices includes, but not limited to: in a first case, the first light-extracting layers 7 are respectively set on the light-outlet sides of the first light-emitting devices 31 and the second light-emitting devices 32, and no first light-extracting layers 7 is set on the light-outlet sides of the third light-emitting devices 33; in a second case, the first light-extracting layers 7 are respectively set on the light-outlet sides of the first light-emitting devices 31 and the third light-emitting devices 33, and no first light-extracting layers 7 is set on the light-outlet sides of the second light-emitting devices 32; in a third case, the first light-extracting layers 7 are respectively set on the light-outlet sides of the second light-emitting devices 32 and the third light-emitting devices 33, and no first light-extracting layers 7 is set on the light-outlet sides of the first light-emitting devices 31; and in a fourth case, the first light-extracting layers 7 are set on the light-outlet sides of a part of the first light-emitting devices 31, a part of the second light-emitting devices 32 and a part of the third light-emitting devices 33, and no first light-extracting layers 7 is set on the light-outlet sides of another part of the first light-emitting devices 31, another part of the second light-emitting devices 32 and another part of the third light-emitting devices 33.

A corresponding relationship between one of the prisms 71 in the first light-extracting layer 7 and the convex lenses 91 in the corresponding second light-extracting layer 9 is not limited here, which may be specifically determined according to an actual situation.

In an exemplary embodiment, one of the prisms 71 corresponds to a row of the convex lenses 91 arranged along the first direction OB. It may be understood that, at this time, an orthographic projection of the one prism 71 on the light-emitting base plate 100, overlaps with orthographic projections of a row of the convex lenses 91 arranged along the first direction OB on the light-emitting base plate 100.

In an exemplary embodiment, one of the prisms 71 corresponds to a row of the convex lenses 91 arranged along the first direction OB. It may be understood that, at this time, the orthographic projection of the one prism 71 on the light-emitting base plate 100, overlaps with orthographic projections of a row of the convex lenses 91 arranged along the first direction OB on the light-emitting base plate 100.

In an exemplary embodiment, the case where the orthographic projection of each of the plurality of first light-extracting layers 7 on the light-emitting base plate 100 is within the orthographic projection of the corresponding one of the plurality of second light-extracting layers 9 on the light-emitting base plate 100, includes, but is not limited to: an outer contour of the orthographic projection of the first light-extracting layer 7 on the light-emitting base plate 100 is within an outer contour of the orthographic projection of the corresponding second light-extracting layer 9 on the light-emitting base plate 100; alternatively, the outer contour of the orthographic projection of the first light-extracting layer 7 on the light-emitting base plate 100, overlaps with the outer contour of the orthographic projection of the corresponding second light-extracting layer 9) on the light-emitting base plate 100.

In an exemplary embodiment, in a condition that the maximum size W of the prism 71 along the second direction OA is equal to the maximum size D of the convex lens 9 along the second direction OA, one of the prisms 71 may correspond to a row of the convex lenses 91 arranged along the first direction OB. In a condition that the maximum size W of the prism 71 along the second direction OA is less than the maximum size D of the convex lens 91 along the second direction OA, a plurality of the prisms 71 may correspond to a row of the convex lenses 91 arranged along the first direction OB.

For example, the maximum size W of the prism 71 along the second direction OA, ranges from 6 μm to 40 μm.

For example, a height of the prism 71 in a direction perpendicular to the light-emitting base plate range 100, ranges from 4 μm to 27 μm.

For example, the maximum size D of the convex lens 91 along the second direction OA, ranges from 6 μm to 50 μm.

For example, a ratio of a height of the convex lens 91 in the direction perpendicular to the light-emitting base plate 100 to the maximum size D of the convex lens 91 along the second direction OA range from 0.1:1 to 1.5:1.

For example, the height of the convex lens 91 in the direction perpendicular to the light-emitting base plate 100 is 5 μm, and the maximum size D of the convex lens 91 along the second direction OA is 50 μm; alternatively, the height of the convex lens 91 in the direction perpendicular to the light-emitting base plate 100 is 0.6 μm, and the maximum size D of the convex lens 91 along the second direction OA is 6 μm; and alternatively, the height of the convex lens 91 in the direction perpendicular to the light-emitting base plate 100 is 9 μm, and the maximum size D of the convex lens 91 along the second direction OA is 6 μm.

A spacing size between every two adjacent ones of the prisms 71 in the first light-extracting layer 7 along the second direction OA is not limited here, which may be specifically determined according to an actual product situation.

For example, the spacing size between every two adjacent ones of the prisms 71 along the second direction OA, ranges from 0.5 μm to 5 μm.

A spacing size between every two adjacent ones of the convex lenses 91 in the second light-extracting layer 9 is not limited here, which may be specifically determined according to an actual product situation.

For example, the spacing size between every two adjacent ones of the prisms 71 along the second direction OA may be set greater than or equal to the spacing size between every two adjacent ones of the convex lenses 91 in the corresponding second light-extracting layer 9 along the second direction OA, so that light emitted from the prisms 71 and light emitted from areas between every two adjacent prisms 71 in the first light-extracting layers 7 may enter more into the convex lenses 91 in the second light-extracting layers 9, so that the convex lens 91 may play a better role in light convergence, thus improving the light-outlet efficiency of the display panel and reducing energy consumption thereof.

In an exemplary embodiment, a shape of the orthographic projection of the prism 71 on the light-emitting base plate 100 is a quadrilateral, and a shape of cross section of the prism 71 in the direction perpendicular to the light-emitting base plate 100 is a triangle.

In an exemplary embodiment, a shape of the orthogonal projection of the convex lens 91 on the light-emitting base plate 100 is a circular, an elliptical, a regular hexagon or other regular polygon, and a shape of cross section of the convex lens 91 in the direction perpendicular to the light-emitting base plate 100 is a semicircle, a semielliptical shape or a fan shape.

An included angle formed by the first direction OB intersecting the second direction OA is not limited here. For example, the included angle formed by the first direction OB intersecting the second direction OA may be a right angle, that is, the first direction OB and the second direction OA are perpendicular to each other.

In an exemplary embodiment, the light-emitting base plate 100 includes a substrate 1 and a plurality of the light-emitting devices 3 located on the substrate 1. For the light-emitting devices 3 whose light-outlet sides are provided with the first light-extracting layers 7, the orthographic projections of the first light-extracting layers 7 on the substrate 1 at least partially cover orthographic projections of the light-emitting devices 3 on the substrate 1.

For example, the orthographic projection of the first light-extracting layer 7 on the substrate 1 partially covers the orthographic projection of the corresponding light-emitting device 3 on the substrate 1. Alternatively, the outer contour of the orthographic projection of the first light-extracting layer 7 on the substrate 1, overlaps with an outer contour of the orthographic projection of the corresponding light-emitting device 3 on the substrate 1. Alternatively, the orthographic projection of the first light-extracting layer 7 on the substrate 1 covers the orthographic projection of the corresponding light-emitting device 3 on the substrate 1, and the first light-extracting layer 7 further extends to an area between the corresponding light-emitting device 3 and an adjacent light-emitting device 3.

A specific type of the above display panel is not limited here.

In some embodiments, the above display panel may be an OLED (Organic Light-Emitting Diode) display panel, a Mini-LED display panel or a Micro-LED display panel. The embodiments of the application take the display panel being the OLED display panel as an example.

In the display panel provided by the embodiments of the present application, the first light-extracting layers 7 are set on the light-outlet sides of at least the part of the light-emitting devices 3. Each of the first light-extracting layer 7 includes the plurality of prisms 71 extending along the first direction and arranged along the second direction. The prisms 71 may refract the light emitted from the light-emitting base plate 100, so as to adjust light-emitting intensity of respective sub-pixels in the display panel at different view angles, thus releasing the problem of color deviation of large view angle of the display panel. The second light-extracting layers 9 are further set, each of the second light-extracting layer 9 includes the plurality of convex lenses 91 arranged in the array, and the plurality of convex lenses 91 arranged in the array may cooperate with the plurality of prisms 71. On the one hand, because the prisms 71 extend along the first direction OB and are arranged along the second direction OA, which may cause a difference of light intensity between the first direction OB and the second direction OA in the display panel, the convex lenses 91 may reduce the difference of light intensity between the first direction OB and the second direction OA in the display panel. On the other hand, the convex lens 91 may play a good role in converging the light emitted from the prisms 71 and the light emitted from the areas between every two adjacent prisms 71 in the first light-extracting layers 7, thus improving light-outlet intensity of the overall display panel and improving display effect thereof. In addition, the maximum size W of the prism 71 along the second direction OA is less than or equal to the maximum size D of the convex lens 91 along the second direction OA, which may make the light passing through the prisms 71 and refracted by the prisms 71 send into the convex lenses 91 as much as possible, thus further improving light-converging function of the convex lenses 91 and thus further improving the light-outlet efficiency thereof.

In some embodiments of the present application, along the second direction OA, the spacing size between every adjacent two prisms 71 is greater than or equal to the spacing size between every adjacent two convex lenses 91.

In an exemplary embodiment, the spacing size between every adjacent two prisms 71 along the second direction OA may be set to zero, and the spacing size between every adjacent two convex lenses 91 arranged along the second direction OA may be set to zero as well. At this time, the spacing size between every adjacent two prisms 71 along the second direction OA is equal to the spacing size between every adjacent two convex lenses 91 arranged along the second direction OA in the second light-extracting layer 9.

It should be noted that, in the drawings of the present application, it is drawn by taking that the spacing size between every adjacent two prisms 71 along the second direction OA is set to zero and the spacing size between every adjacent two convex lenses 91 arranged along the second direction OA is set to zero as well, as an example.

In the embodiments provided by the present application, the spacing size of every adjacent two prisms 71 along the second direction OA is set less than or equal to the spacing size between every adjacent two convex lenses 91 arranged along the second direction OA in the second light-extracting layer 9, so that the light emitted from the prisms 71 and the light emitted from the areas between every two adjacent prisms 71 in the first light-extracting layers 7 may enter more into the convex lenses 91 in the second light-extracting layers 9, thus further improving the light-converging function of the convex lenses 91 and thus further improving the light-outlet efficiency thereof

In some embodiments of the present application, referring to that shown in FIG. 4, for the first light-extracting layer 7 and the second light-extracting layer 9 located on the light-outlet side of the same light-emitting device 3, the outer contour S1 of the orthographic projection of the first light-extracting layer 7 on the light-emitting base plate 100 is located within the outer contour S2 of the orthographic projection of the second light-extracting layer 9 on the light-emitting base plate 100.

In the display panel provided by the embodiments of the present application, the prisms 71 may refract the light emitted from the light-emitting base plate 100, so the prisms 71 adjust the light intensity of the respective sub-pixels in the display panel at different view angles, and at the same time, the prisms 71 scatter the light. By setting that the outer contour S1 of the orthographic projection of the first light-extracting layer 7 on the light-emitting base plate 100 is located within the outer contour S2 of the orthographic projection of the second light-extracting layer 9 on the light-emitting base plate 100, it makes the light scattered by the first light-extracting layer 7 send into the second light-extracting layer 9 as much as possible, which plays a role of light-converging function, thus improving light-outlet intensity of a center view angle, and thus improving the light-outlet efficiency and reducing power consumption of the display panel.

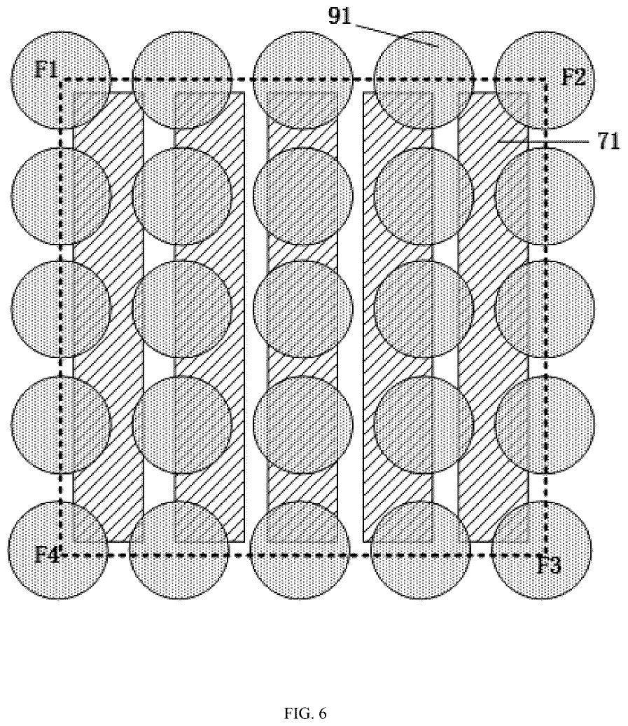

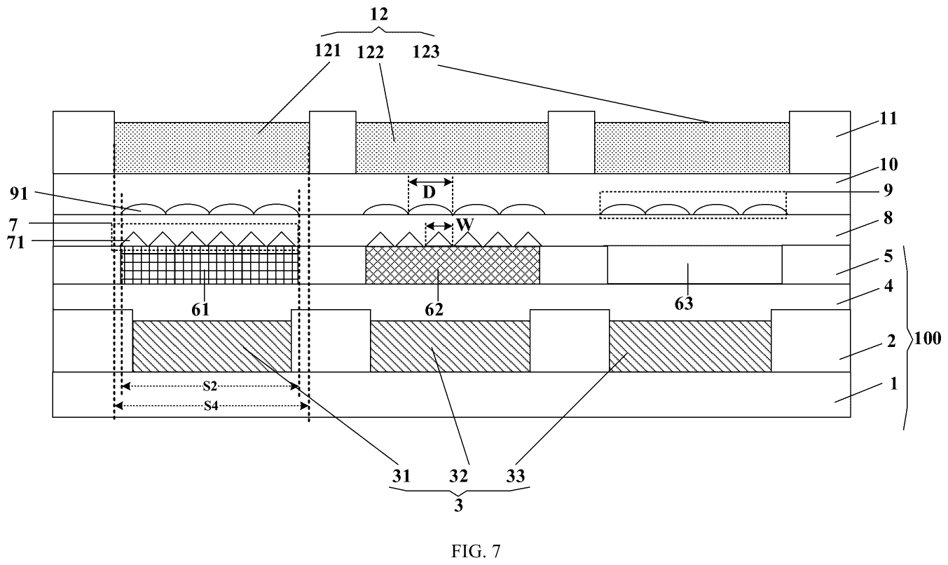

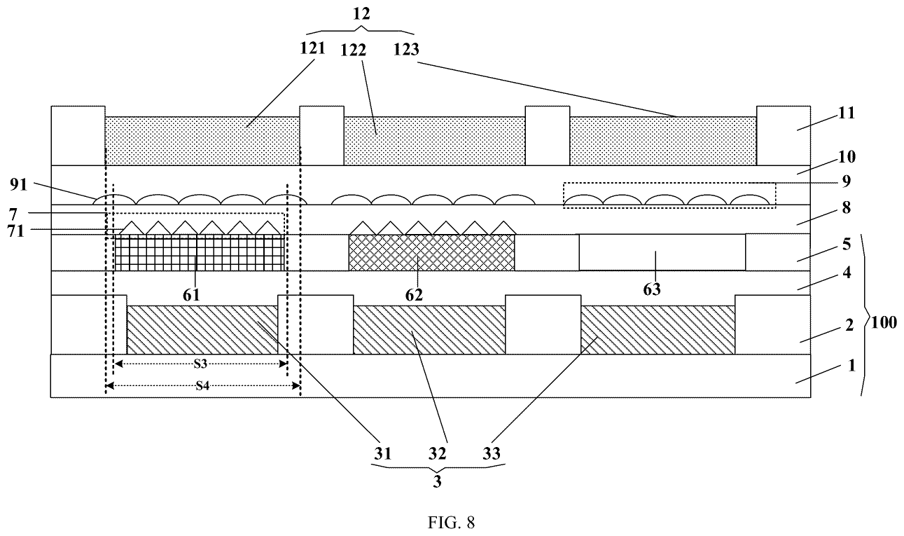

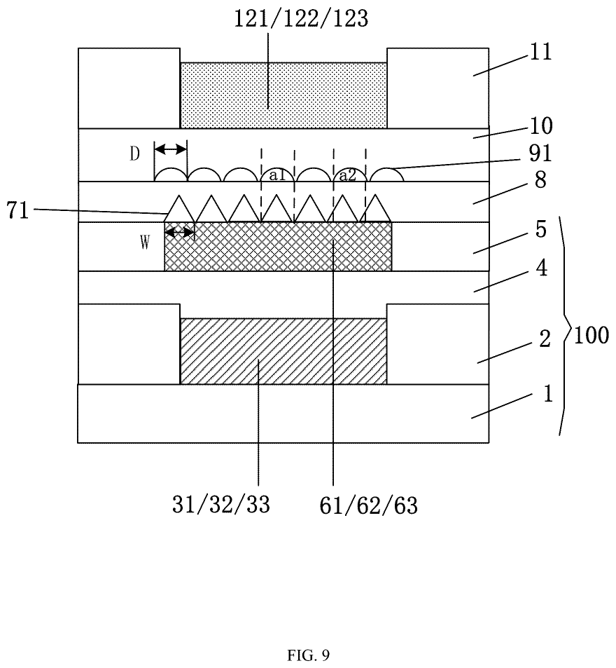

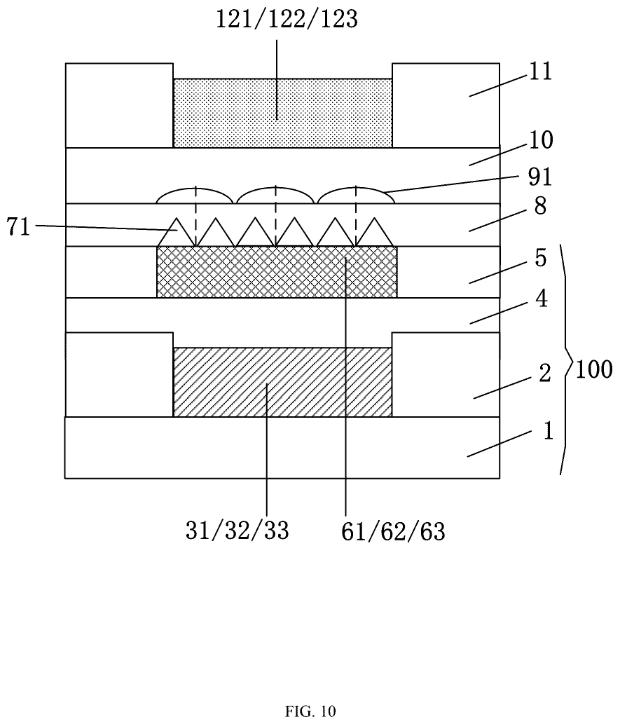

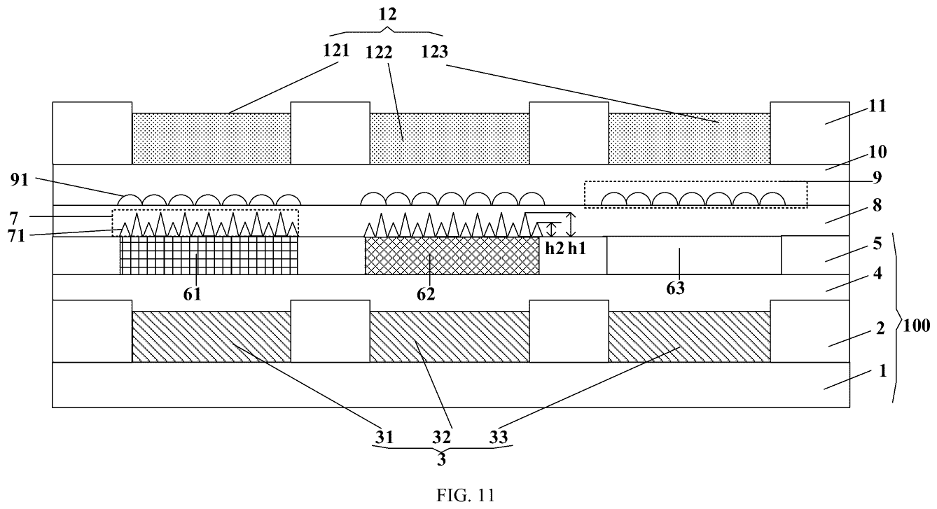

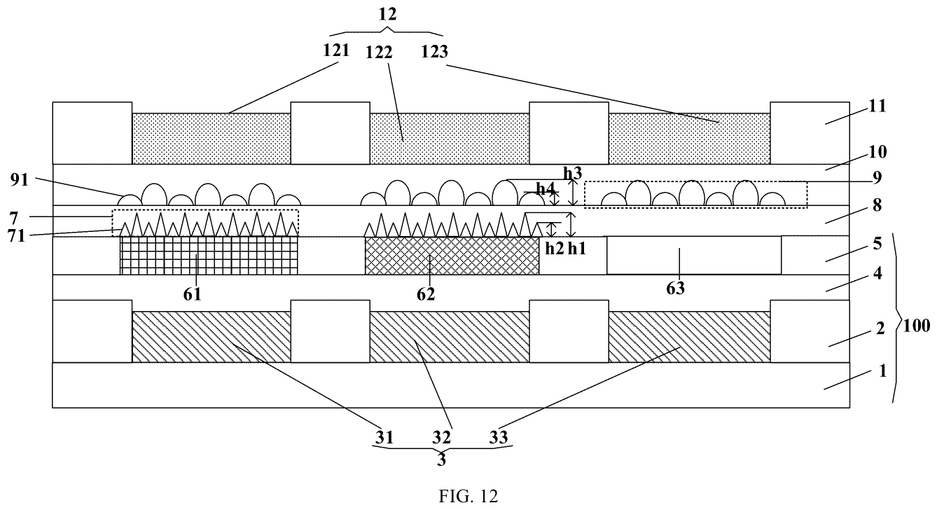

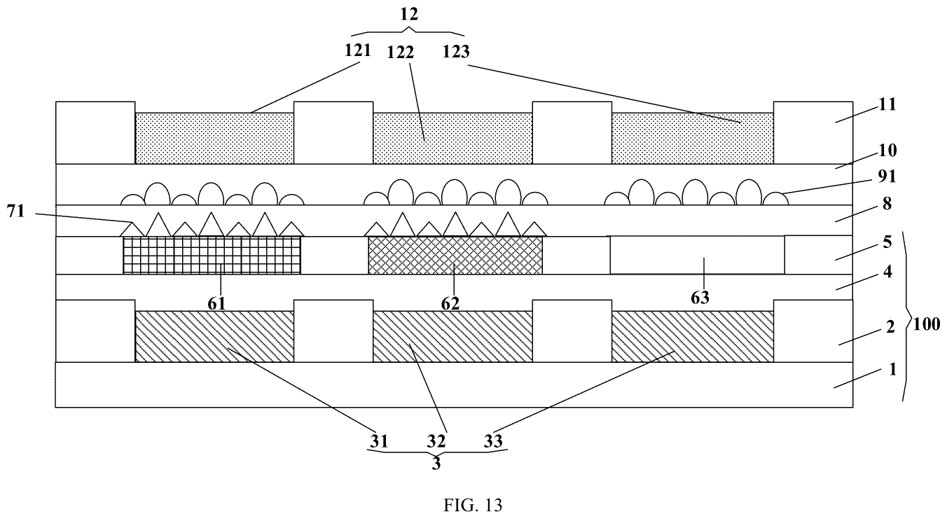

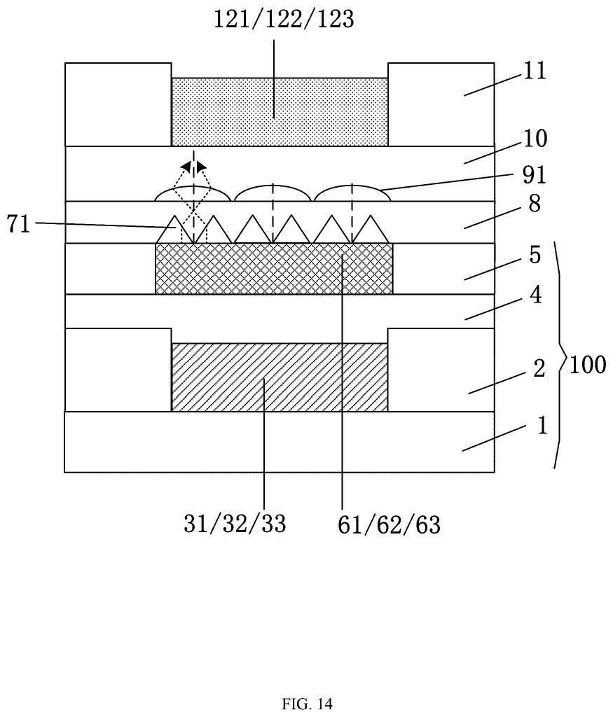

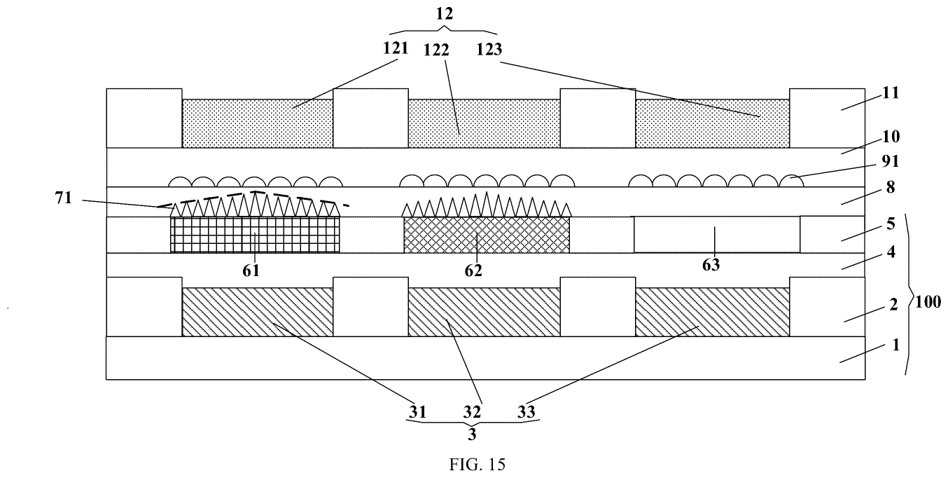

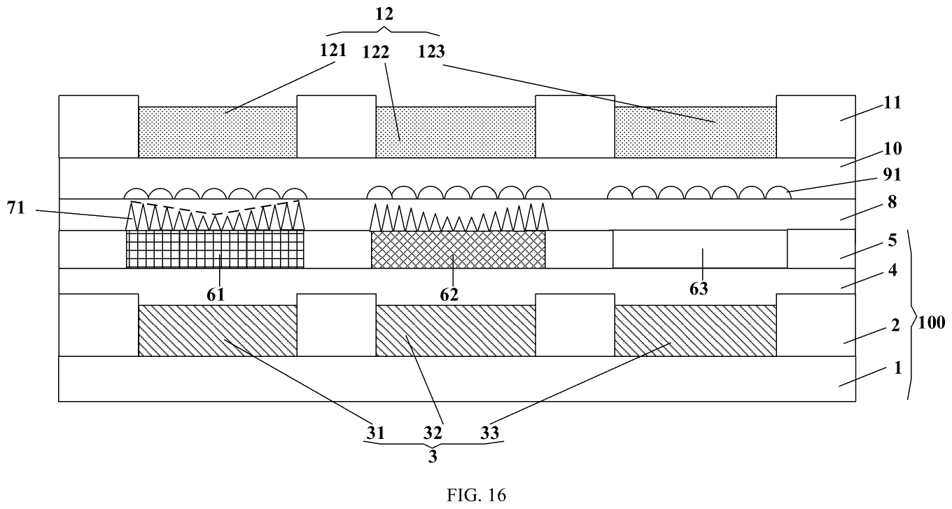

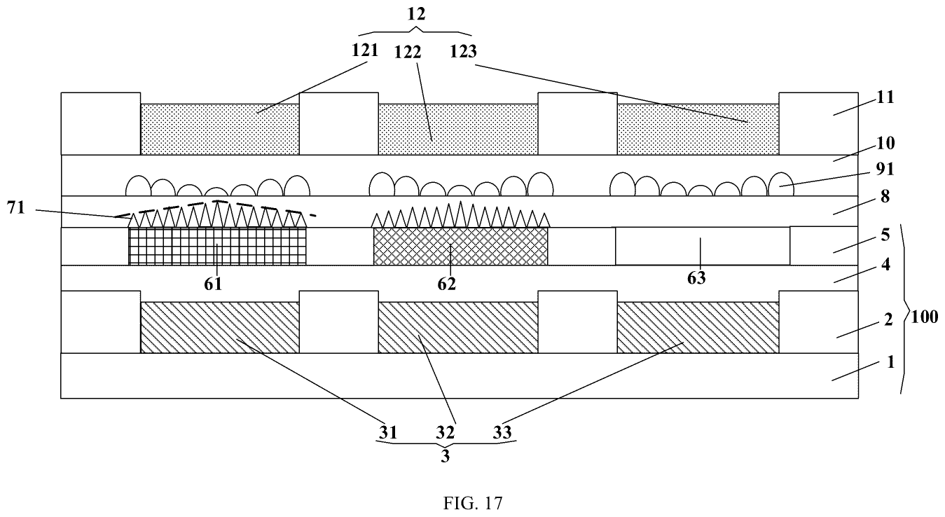

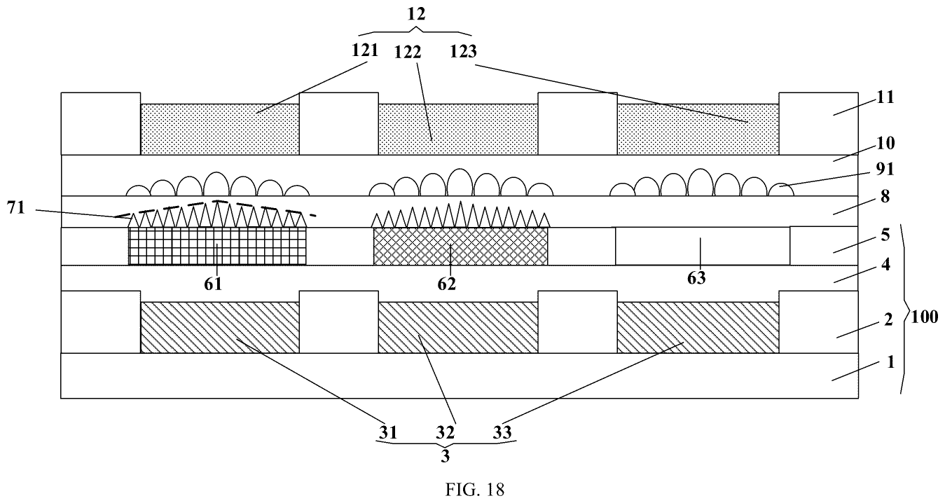

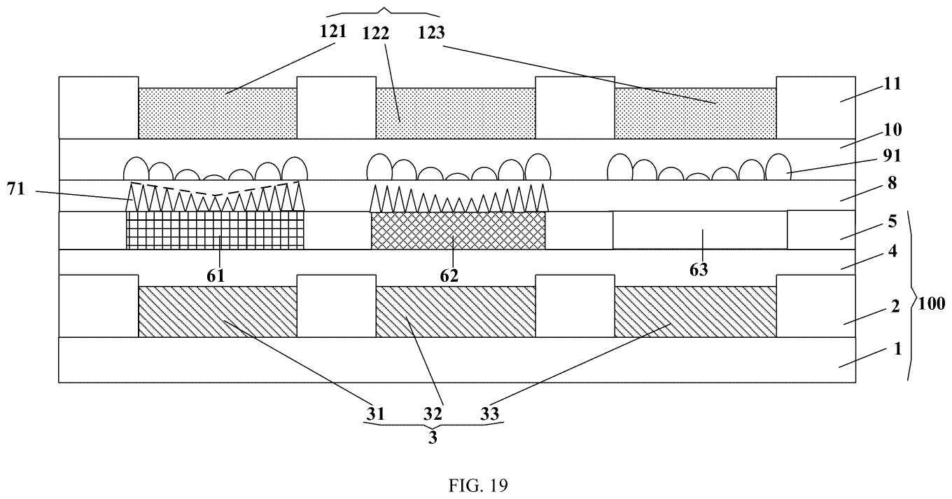

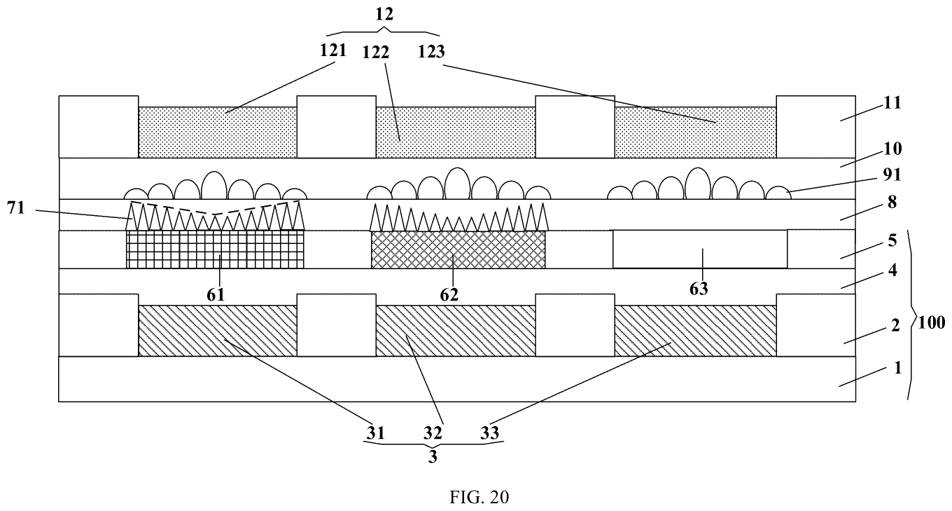

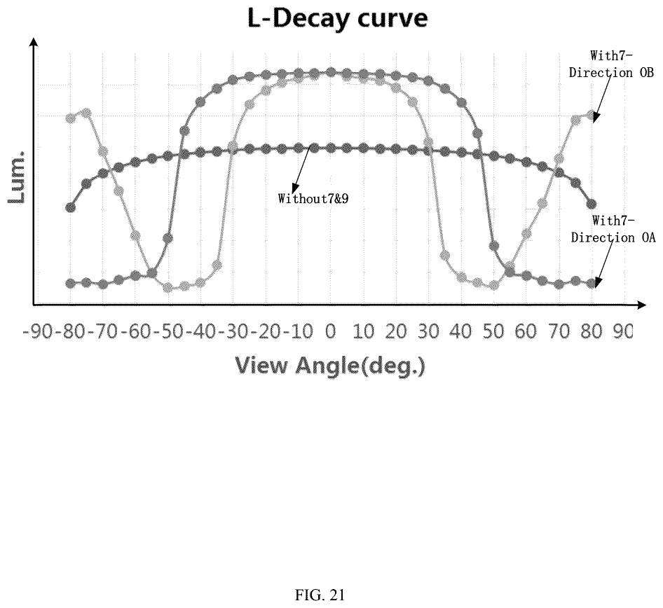

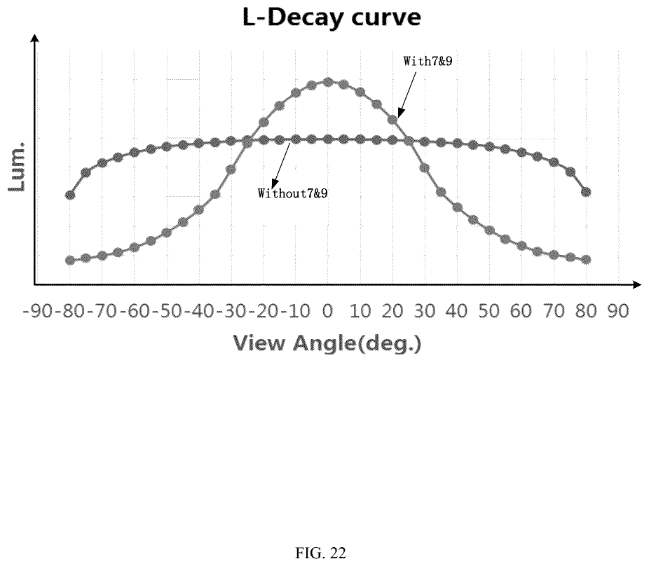

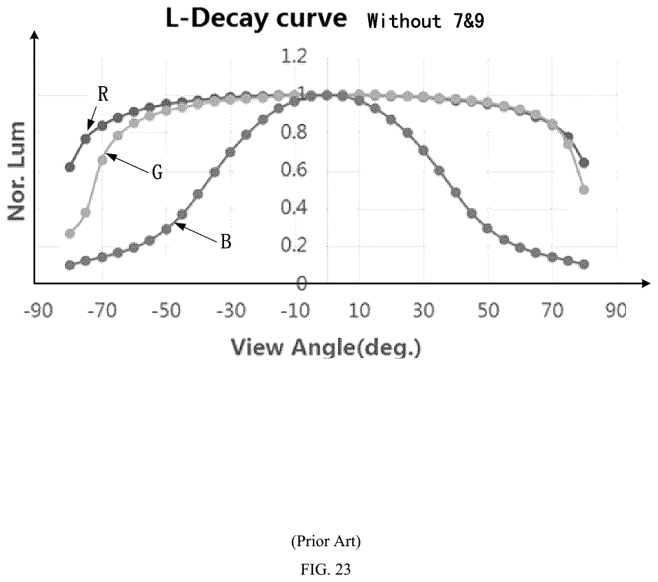

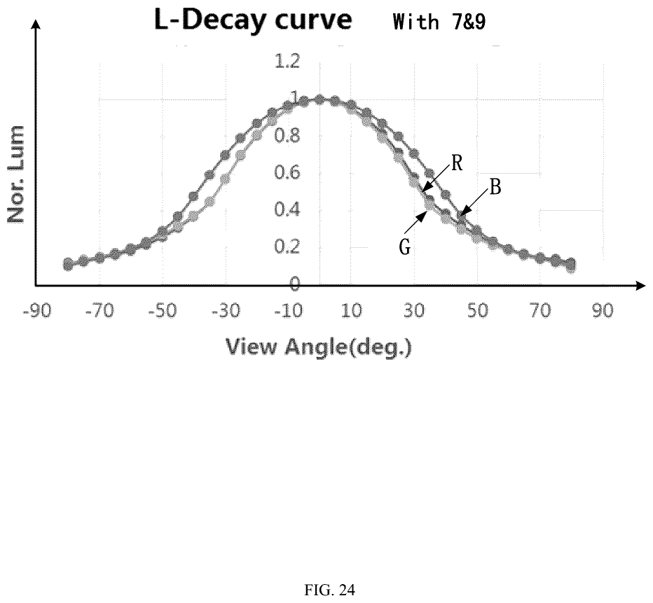

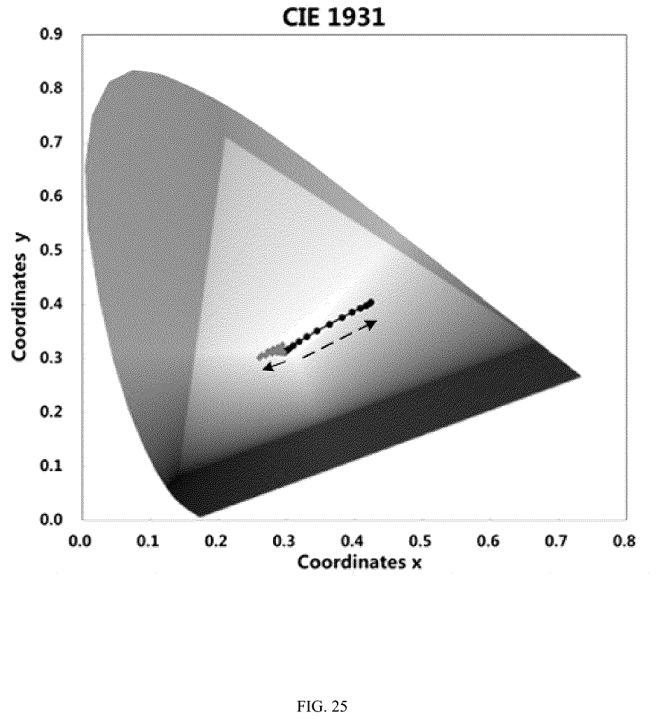

In some embodiments of the present application, as shown in a combination of FIG. 5 and FIG. 6, for the first light-extracting layer 7 (including the plurality of prisms 71) and the second light-extracting layer 9 (including the plurality of convex lenses 91) located on the light-outlet side of the same light-emitting device 3, the outer contour of the orthographic projection of the first light-extracting layer 7 on the light-emitting base plate 100 is within an outer contour of an orthographic projection of a first graph FIF2F3F4 on the light-emitting base plate 100. The first graph FIF2F3F4 is a closed graph formed by successively connecting focuses of the convex lenses 91 of an outermost lap in the second light-extracting layer 9.

In the embodiment of the present application, the outer contour of the orthographic projection of the first light-extracting layer 7 on the light-emitting base plate 100 is located within the outer contour of the orthographic projection of the first graph FIF2F3F4 on the light-emitting base plate 100, and the first graph FIF2F3F4 is the closed graph formed by successively connecting the focuses of the convex lenses 91 of the outermost lap in the second light-extracting layer 9, which makes the light scattered by the first light-extracting layer 7 send into the second light-extracting layer 9 as much as possible, which plays the role of light-converging function to a large extent, thus improving the light-outlet intensity of the center view angle, and thus improving the light-outlet efficiency and reducing the power consumption of the display panel.

In some embodiments of the present application, referring to that shown in FIG. 7, the display panel further includes a plurality of color-resistance layers 12. The plurality of color-resistance layers 12 include a plurality of color-resistance patterns arranged in an array (such as 121, 122 or 123). The color-resistance layers 12 are located on a side of the second light-extracting layers 9 away from the light-emitting base plate 100. The outer contour S2 of the orthographic projection of each of the second light-extracting layers 9 on the light-emitting base plate 100 is located within an outer contour S4 of an orthographic projection of the corresponding one of the color-resistance layers 12 on the light-emitting base plate 100.

In some embodiments of the present application, referring to that shown in FIG. 8, the display panel further includes the plurality of color-resistance layers 12. The plurality of color-resistance layers 12 include the plurality of color-resistance patterns arranged in the array (such as 121, 122 or 123). The color-resistance layers 12 are located on the side of the second light-extracting layers 9 away from the light-emitting base plate 100. The orthographic projection of the second light-extracting layer 9 on the light-emitting base plate 100 and the orthographic projection of the corresponding color-resistance layer 12 on the light-emitting base plate 100, partially overlap to each other, and the outer contour S3 of the orthographic projection of the first graph FIF2F3F4 on the light-emitting base plate 100 is located within the outer contour S4 of the orthographic projection of the corresponding color-resistance layer 12 on the light-emitting base plate 100.

In an exemplary embodiment, referring to that shown in FIG. 1, the color-resistance layers 12 include the first color-resistance pattern 121, the second color-resistance pattern 122 and the third color-resistance pattern 123, and colors of the first color-resistance pattern 121, the second color-resistance pattern 122 and the third color-resistance pattern 123 are different from each other.

For example, the color of the first color-resistance pattern 121 is the same as a color of light emitted from a first color-converting pattern 61, the color of the second color-resistance pattern 122 is the same as a color of light emitted from a second color-converting pattern 62, and the color of the third color-resistance pattern 123 is the same as a color of light emitted from a light-transmitting pattern 63.

In some embodiments, a black matrix layer 11 may be set between every two adjacent color-resistance patterns, to avoid color mixing of the color-resistance patterns of different colors.

In some embodiments, superimposing the color-resistance patterns may be used as a light-shielding layer, to avoid color mixing of color-resistance patterns of different colors.

For example, a thickness of the respective color-resistance patterns in the direction perpendicular to the light-emitting base plate 100, ranges from 5 μm to 25 μm.

The thicknesses of the above color-resistance patterns of different colors may be the same, or the thicknesses of the above color-resistance patterns of different colors may be different from each other, which is not limited here.

In the display panel provided by the embodiments of the present application, the outer contour S2 of the orthographic projection of the second light-extracting layer 9 on the light-emitting base plate 100 is located within the outer contour S4 of the orthographic projection of the color-resistance layer 12 on the light-emitting base plate 100, alternatively, the outer contour S3 of the orthographic projection of the first graph F1F2F3F4 on the light-emitting base plate 100 is located within the outer contour S4 of the orthographic projection of the color-resistance layer 12 on the light-emitting base plate 100, which may make the light converged by the second light-extracting layer 9 emit as much as possible from the color-resistance layer 12, so as to avoid the light being blocked by the black matrix layer 11 between the color resistance patterns, thus improving the light-outlet intensity and light-outlet efficiency of the display panel, and reducing the power consumption thereof.

In some embodiments of the present application, referring to that shown in FIG. 1, the display panel includes the substrate 1, color-converting layers (including the first color-converting patterns 61 and the second color-converting patterns 62), and the color-resistance layers 12. The color-converting layers are located between a part of the light-emitting devices 3 and the corresponding first light-extracting layers 7, and the color-resistance layers 12 are located on the side of the second light-extracting layers 9 away from the light-emitting base plate 100. Among them, orthographic projections of the respective color-converting layers (including the first color-converting patterns 61 and the second color-converting patterns 62) on the substrate 1 cover the orthographic projections of at least a part of the light-emitting devices 3 on the substrate 1, and the orthographic projections of the color-resistance layers 12 on the substrate 1, overlap with the orthographic projections of the corresponding color-converting layers (including the first color-converting patterns 61 and the second color-converting patterns 62) on the substrate 1.

For example, the color-converting layers includes the first color-converting patterns 61 and the second color-converting patterns 62. For example, the first color-converting patterns 61 may be set as red-converting patterns, and the second color-converting patterns 62 may be set as green-converting patterns. For another example, the first color-converting patterns 61 may be set as the green-converting patterns, and the second color-converting patterns 62 may be set as the red-converting patterns.

For example, the light-emitting devices 3 include the first light-emitting devices 31, the second light-emitting devices 32 and the third light-emitting devices 33. The color-converting layers include the first color-converting patterns 61 on light-outlet sides of the respective first light-emitting devices 31, and the second color-converting patterns 62 on light-outlet sides of the respective second light-emitting devices 32. The display panel further includes the light-transmitting patterns 63 located on light-outlet sides of the respective third light-emitting devices 33. The light-transmitting patterns 63 are arranged on the same layer as the color-converting layers (including 61 and 62).

Among them, light-emitting colors of the first light-emitting devices 31, the second light-emitting devices 32 and the third light-emitting devices 33 are the same, and colors of light converted by the first color-converting patterns 61, light converted by the second color-converting patterns 62, and light converted by the light-transmitting patterns 63 are different from each other.

In some embodiments, a barrier layer 5 is arranged between any two adjacent ones of the first color-converting pattern 61, the second color-converting pattern 62, and the light-transmitting pattern 63.

For example, a material of the barrier layer 5 may include an organic material, wherein the material of the barrier layer 5 may be the same as that of the black matrix layer 11, or the material of the barrier layer 5 may be different from that of the black matrix layer 11, which may be determined according to an actual situation, and is not limited here.

In some embodiments, the light-emitting colors of the first light-emitting devices 31, the second light-emitting devices 32 and the third light-emitting devices 33 are the same, and the light-emitting colors are all blue. The first color-converting patterns 61 may be set as the red-converting patterns, and the second color-converting patterns 62 may be set as the green-converting patterns. At this time, light emitted by the first light-emitting devices 31 and passing through the first color-converting patterns 61 is red, and light emitted by the second light-emitting devices 32 and passing through the second color-converting pattern 62 is green.

In an exemplary embodiment, a pixel-definition layer 2 is arranged between any two adjacent ones of the first light-emitting device 31, the second light-emitting device 32 and the third light-emitting device 33.

In an exemplary embodiment, referring to that shown in FIG. 1, the light-emitting base plate 100 includes the substrate 1, the light-emitting devices 3 located on the substrate 1, packaging layers 4 covering the respective light-emitting devices 3, the first color-converting pattern 61, the second color-converting pattern 62, the light-transmitting pattern 63, and the barrier layer 5 located between any two adjacent ones of the first color-converting pattern 61, the second color-converting pattern 62, and the light-transmitting pattern 63. The color-resistance layers 12 include the first color-resistance pattern 121, the second color-resistance pattern 122, and the third color-resistance pattern 123.

For example, the display panel includes a plurality of sub-pixels arranged in an array, and the plurality of sub-pixels include first sub-pixels, second sub-pixels and third sub-pixels, wherein each of the first sub-pixels includes the first light-emitting device 31, the first color-converting pattern 62, the first color-resistance pattern 121, and the first light-extracting layer 7 and the second light-extracting layer 9 located between the first color-converting pattern 62 and the first color-resistance pattern 121. Among them, an orthographic projection of the first light-emitting device 31 on the substrate 1 is within an orthographic projection of the first color-converting pattern 62 on the substrate 1, and the orthographic projection of the first color-converting pattern 62 on the substrate 1 is within an orthographic projection of the first color-resistance pattern 121 on the substrate 1. It may be understood that an area of the orthographic projection of the first color-converting pattern 62 on the substrate 1 is greater than or equal to that of the orthographic projection of the first light-emitting device 31 on the substrate 1, and an area of the orthographic projection of the first color-resistance pattern 121 on the substrate 1 is greater than or equal to that of the orthographic projection of the first color-converting pattern 62 on the substrate 1.

For example, a ratio of the area of the orthographic projection of the first color-resistance pattern 121 on the substrate 1 to the area of the orthographic projection of the first color-converting pattern 62 on the substrate 1, ranges from 1:1 to 1.3:1.

Whether shapes of the orthographic projections of the first light-emitting device 31, the first color-converting pattern 62, and the first color-resistance pattern 121 on the substrate 1 are the same, is not limited here, which may be determined according to an actual situation.

Each of the second sub-pixels includes the second light-emitting device 32, the second color-converting pattern 62, the second color-resistance pattern 122, and the first light-extracting layer 7 and the second light-extracting layer 9 located between the second color-converting pattern 62 and the second color-resistance pattern 122. Among them, an orthographic projection of the second light-emitting device 32 on the substrate 1 is within an orthographic projection of the second color-converting pattern 62 on the substrate 1, and the orthographic projection of the second color-converting pattern 62 on the substrate 1 is within an orthographic projection of the second color-resistance pattern 122 on the substrate 1. It may be understood that an area of the orthographic projection of the second color-converting pattern 62 on the substrate 1 is greater than or equal to that of the orthographic projection of the second light-emitting device 32 on the substrate 1, and an area of the orthographic projection of the second color-resistance pattern 122 on the substrate 1 is greater than or equal to that of the orthographic projection of the second color-converting pattern 62 on the substrate 1.

For example, a ratio of the area of the orthographic projection of the second color-resistance pattern 122 on the substrate 1 to the area of the orthographic projection of the second color-converting pattern 62 on the substrate 1, ranges from 1:1 to 1.3:1.

Whether shapes of the orthographic projections of the second light-emitting device 32, the second color-converting pattern 62, and the second color-resistance pattern 122 on the substrate 1 are the same, is not limited here, which may be determined according to an actual situation.

Each of the third sub-pixels includes the third light-emitting device 33, the light-transmitting pattern 63, the third color-resistance pattern 123, and the second light-extracting layer 9 between the light-transmitting pattern 63 and the third color-resistance pattern 123. Among them, an orthographic projection of the third light-emitting device 33 on the substrate 1 is within an orthographic projection of the light-transmitting pattern 63 on the substrate 1, and the orthographic projection of the light-transmitting pattern 63 on the substrate 1 is within an orthographic projection of the third color-resistance pattern 123 on the substrate 1. It may be understood that an area of the orthographic projection of the light-transmitting pattern 63 on the substrate 1 is greater than or equal to that of the orthographic projection of the third light-emitting device 33 on the substrate 1, and an area of the orthographic projection of the third color-resistance pattern 123 on the substrate 1 is greater than or equal to that of the orthographic projection of the light-transmitting pattern 63 on the substrate 1.

For example, a ratio of the area of the orthographic projection of the third color-resistance pattern 123 on the substrate 1 to the area of the orthographic projection of the light-transmitting pattern 63 on the substrate 1, ranges from 1:1 to 1.3:1.

Whether shapes of the orthographic projections of the third light-emitting device 33, the light-transmitting pattern 63, and the third color-resistance pattern 123 on the substrate 1 are the same, is not limited here, which may be determined according to an actual situation.

In some embodiments of the present application, the first color-converting pattern 61 and the second color-converting pattern 62 respectively include quantum dots, and the light-transmitting pattern 63 includes scattering particles.

For example, the scattering particles include at least one kind of: titanium dioxide (TiO2) particles, and zirconia (ZrO3) particles.

For example, thicknesses of the first color-converting pattern 61, the second color-converting pattern 62, and the light-transmitting pattern 63 in the direction perpendicular to the substrate 1, ranges from 5 μm to 20 μm.

For example, the thicknesses of the first color-converting pattern 61, the second color-converting pattern 62, and the light-transmitting pattern 63 in the direction perpendicular to the substrate 1, are equal to each other.

In some embodiments of the present application, referring to that shown in FIG. 9 or FIG. 10, the orthographic projections of a row of the convex lenses 91 on the light-emitting base plate 100, overlap with the orthographic projection of at least one of the prisms 71 on the light-emitting base plate 100.

In an exemplary embodiment, referring to that shown in FIG. 9, the orthographic projections of a row (row a1) of the convex lenses 91 arranged along the first direction OB on the light-emitting base plate 100, overlap with the orthographic projection of one of the prisms 71 on the light-emitting base plate 100. The orthographic projections of a row (row a2) of the convex lenses 91 arranged along the first direction OB on the light-emitting base plate 100, overlap with the orthographic projections of two of the prisms 71 on the light-emitting base plate 100.

In an exemplary embodiment, referring to that shown in FIG. 10, the orthographic projections of each row of the convex lenses 91 arranged along the first direction OB on the light-emitting base plate 100, overlap with the orthographic projections of two of the prisms 71 on the light-emitting base plate 100. It may be understood that two prisms 71 correspond to a row of the convex lenses 91.

In the embodiments of the present application, the orthographic projections of a row of the convex lenses 91 on the light-emitting base plate 100, are set to overlap with the orthographic projection of at least one of the prisms 71 on the light-emitting base plate 100, so that the convex lenses 91 may converge the light emitted from the prisms 71 as much as possible, and then the light emit through the color-resistance layer 12, thus improving the light-outlet efficiency of the display panel.

In some embodiments of the present application, referring to that shown in FIG. 9 or FIG. 10, along the second direction OA, the number of the prisms 71 included in the first light-extracting layer 7 is greater than or equal to the number of the convex lenses 91 included in the second light-extracting layer 9.

In some embodiments of the present application, referring to that shown in FIG. 11, the first light-extracting layers 7 include first prisms (unmarked) and second prisms (unmarked), and the first prisms and the second prisms are spaced from each other. Maximum sizes of the first prisms and the second prisms along the second direction OA are the same, and a height h1 of the first prisms in the direction perpendicular to the light-emitting base plate 100 is greater than or equal to a height h2 of the second prisms in the direction perpendicular to the light-emitting base plate 100.

In the display panel provided by the embodiments of the application, the plurality of prisms 71 extend along the first direction OB and arranged along the second direction OA, so the plurality of prisms 71 may cause that the difference of light intensity between the first direction OB and the second direction OA in the display panel is relatively big, and that a sudden increase of light intensity may occur in the display panel at a large view angle along the second direction OA. In the embodiments of the present application, by setting that the maximum sizes of the respective prisms 71 along the second direction OA are the same, and that the heights of every two adjacent ones of the prisms 71 in the direction perpendicular to the light-emitting base plate 100 are different from each other, to make slopes of sides of every two adjacent ones of the prisms 71 are different from each other, so that refractive functions of every two adjacent ones of the prisms 71 on light are different from each other, which may release a problem that the difference of light intensity between the first direction OB and the second direction OA in the display panel is relatively big, to a certain extent, thus improving the display effect thereof. In addition, after the second light-extracting layers 9 are set, the plurality of convex lenses 91 may converge light, to improve brightness of the center view angle, and at the same time, to further release the problem that the difference of light intensity between the first direction OB and the second direction OA in the display panel is relatively big, thus further improving the display effect of the display panel.

In some embodiments of the present application, referring to that shown in FIG. 12, the second light-extracting layers 9 include first convex lenses (unmarked) and second convex lenses (unmarked). Along the second direction OA, the first convex lenses and the second convex lenses are spaced from each other. Maximum sizes of the first convex lenses and the second convex lenses along the second direction OA are the same, and a height h3 of the first convex lenses in the direction perpendicular to the light-emitting base plate 100 is greater than or equal to a height h4 of the second convex lenses in the direction perpendicular to the light-emitting base plate 100.

In some embodiments of the present application, referring to that shown in FIG. 13, along the second direction OA, the number of the prisms 71 included in the first light-extracting layer 7 is equal to the number of convex lenses 91 included in the second light-extracting layer 9. An orthographic projection of the first convex lens (with a higher height) on the light-emitting base plate 100, overlaps with an orthographic projection of the first prism (with a higher height) on the light-emitting base plate 100, and an orthographic projection of the second convex lens (with a lower height) on the light-emitting base plate 100, overlaps with an orthographic projection of the second prism (with a lower height) on the light-emitting base plate 100.

In an exemplary embodiment, in a condition that the maximum sizes of the convex lenses 91 along the second direction OA are the same, the higher the height of the convex lens 91, the stronger a light-converging ability thereof. In a condition that the maximum sizes of the prisms 71 along the second direction OA are the same, the higher the height of the prism 71, the stronger a light-refracting ability thereof.

In the embodiments of the present application, the number of the prisms 71 in the first light-extracting layer 7 and the number of the convex lenses 91 distributed along the second direction OA in the second light-extracting layer 9 are set to be the same, the higher prisms 71 are set to correspond to the higher convex lenses 91, and the lower prisms 71 are set to correspond to the lower convex lenses 91, such that the prisms 71 with stronger light-refracting ability correspond to the convex lenses 91 with stronger light-converging ability, and the prisms 71 with weak light-refracting ability correspond to the convex lenses 91 with weak light-converging ability, which make the light refracted by the prisms 71 be converged by the convex lens 91 as much as possible. On the one hand, the prisms 71 may refract the light emitted from the light-emitting base plate 100, so as to adjust the light intensity of the respective sub-pixels in the display panel at different view angles, thus releasing the problem of color deviation of large view angle of the display panel. On the other hand, the convex lenses 91 may reduce the difference of light intensity between the first direction OB and the second direction OA in the display panel, so as to adjust difference of brightness attenuation of lights with different colors at a large view angle; and the convex lenses 91 may further improve the light-converging ability thereof, and improve brightness of the display panel of the center view angle, thus improving the display effect of the display panel.

In some embodiments of the present application, referring to that shown in FIG. 14, along the second direction OA, the number of prisms 71 included in the first light-extracting layer 7 is greater than the number of convex lenses 91 included in the second light-extracting layer 9.

For example, the number of prisms 71 included in the first light-extracting layer 7 is N. and the number of convex lenses 91 included in the second light-extracting layer 9 is N+1; or, the number of prisms 71 included in the first light-extracting layer 7 is N. and the number of convex lenses 91 included in the second light-extracting layer 9 is 2N; wherein N is a positive integer.

In some embodiments of the present application, referring to that shown in FIG. 14, the orthographic projections of a row of the convex lenses 91 on the light-emitting base plate 100, overlap with the orthographic projections of two adjacent prisms 71 on the light-emitting base plate 100, and an orthographic projection of a line connecting the focuses of the row of convex lenses 91 on the light-emitting base plate 100 is located between the orthographic projections of the two adjacent prisms 71 on the light-emitting base plate 100.

In this way, the two prisms 71 correspond to the row of convex lenses 91, a part of light refracted by the prism 71 on left enters into a right position of the convex lens 91, a part of light refracted by the prism 71 on right enters into a left position of the convex lens 91, and light emitted from an area between the two prisms 71 enters into a position near a geometric center of the convex lens 91, which finally converges as much light as possible through the convex lens 91, thus improving brightness of the center view angle, such that the display effect of the display panel is improved.

In some embodiments of the present application, referring to that shown in FIG. 15 and FIG. 16, the first light-extracting layer 7 includes a middle region and edge regions on both sides of the middle region, wherein the heights of the respective prisms 71 in the first light-extracting layer 7 in the direction perpendicular to the light-emitting base plate 100 gradually decrease along a third direction. The third direction is a direction from the edge region to the middle region, or the third direction is a direction from the middle region to the edge region.

In an exemplary embodiment, referring to that shown in FIG. 15, the heights of the respective prisms 71 in the first light-extracting layer 7 in the direction perpendicular to the light-emitting base plate 100 gradually decrease along the direction from the middle region to the edge region.

In practical applications, a side of the first light-extracting layer 7 away from the light-emitting device 3 is further set with the color-resistance layer 12 and the black matrix layer 11, and if the prism 71 located at an edge region of a light-outlet side of the light-emitting device 3 is higher, light emitted from the edge region of the light-emitting device 3 and refracted by the higher prism 71 at the edge region, very likely will not emit out of the color-resistance layer 12, but will emit into the black matrix layer 11 to be absorbed, which greatly reduces light-outlet intensity of the display panel and reduces the display effect thereof. In the embodiments of the present application, by setting a structure of the first light-extracting layer 7 as shown in FIG. 15, the height of the prism 71 located at a middle region of the light-outlet side of the light-emitting device 3 is greater than the height of the prism 71 located at the edge region of the light-outlet side of the light-emitting device 3. In this way, the higher prism 71 has a strong refractive function on the light emitted from the light-emitting device 3 (with a large refractive angle), and the lower prism 71 has a weak refractive function on the light emitted from the light-emitting device 3 (with a small refractive angle), which makes the refractive angle of the light emitted from the edge region of the light-emitting device 3 smaller to reduce loss of the light, and makes the refractive angle of the light emitted from the middle region larger, so as to adjust the light-outlet intensity of different view angles, thus releasing the problem of color deviation of different view angles, and at the same time, avoiding reducing the light-outlet intensity of the center view angle.

In an exemplary embodiment, referring to that shown in FIG. 16, the heights of the respective prisms 71 in the first light-extracting layer 7 in the direction perpendicular to the light-emitting base plate 100 gradually increase along the direction from the middle region to the edge region.

In the embodiments of the present application, before the first light-extracting layer 7 and the second light-extracting layer 9 are set, if the condition that the brightness attenuation of lights with different colors at different view angles is inconsistent occurs (for example, the brightness attenuation of blue light is severe along with increase of the view angle, but the brightness attenuation of red light and green light is small along with increase of the view angle), in order to make the brightness attenuation of lights with different colors at different view angles consistent along with increase of the view angle, the first light-extracting layers 7 may be set on light-outlet sides of the first color-converting pattern 61 and the second color-converting pattern 62, and the heights of the respective prisms 71 in the first light-extracting layer 7 in the direction perpendicular to the light-emitting base plate 100 are made gradually increase along the direction from the middle region to the edge region. In this way, the prisms 71 may adjust angles of the lights emitted from the first color-converting pattern 61 and the second color-converting pattern 62, and at the same time, the prisms 71 may, to a certain extent, increase the attenuation of the lights emitted from the first color-converting pattern 61 and the second color-converting pattern 62 along with increase of the view angle, such that the lights with different colors attenuate consistently along with increase of the view angle, thus releasing the problem of color deviation of large view angle of the display panel.

In some embodiments of the present application, referring to that shown in FIG. 17, FIG. 18, FIG. 19 and FIG. 20, the second light-extracting layer 9 includes a center region and a peripheral region surrounding the center region, and the heights of the respective convex lenses 91 in the second light-extracting layer in the direction perpendicular to the light-emitting base plate 100 gradually decrease along a fourth direction. The fourth direction is a direction from the peripheral region to the center region, or the fourth direction is a direction from the center region to the peripheral region.

In an exemplary embodiment, referring to that shown in FIG. 17, the heights of the prisms 71 in the first light-extracting layer 7 gradually decrease from a middle to both sides, and the heights of the convex lenses 91 in the second light-extracting layer 9 gradually increase from the center region to the peripheral region surrounding the center region.

In this way, the prisms 71 in the first light-extracting layer 7 refract the light emitted from the middle region of the light-emitting device 3 by a larger refractive angle (which may be understood as a larger degree of deviation from the center view angle), and refract the light emitted from the edge region of the light-emitting device 3 by a smaller refractive angle (which may be understood as a smaller degree of deviation from the center view angle), so that the light may pass through the second light-extracting layer 9 and emit out of the display panel as much as possible, which improves the light-outlet intensity of the display panel. In addition, the convex lens 91 located at the periphery region of the second light-extracting layer 9 has a stronger light-converging ability than the convex lens located at the center region thereof, which largely avoids that the light emitted from the periphery region enters into the black matrix layer 11, so as to make the light emitted out the color-resistance layer 12, thus further improving the light-outlet intensity of center view angle of the display panel, so as to improve the brightness of the display panel, and reduce power consumption thereof.

In an exemplary embodiment, referring to that shown in FIG. 18, the heights of the prisms 71 in the first light-extracting layer 7 gradually decrease from the middle to the both sides, and the heights of the convex lenses 91 in the second light-extracting layer 9 gradually decrease from the center region to the peripheral region surrounding the center region.

In an exemplary embodiment, referring to that shown in FIG. 19, the heights of the prisms 71 in the first light-extracting layer 7 increase gradually from the middle to the both sides, and the heights of the convex lenses 91 in the second light-extracting layer 9 increase gradually from the center region to the peripheral region surrounding the center region.

In an exemplary embodiment, referring to that shown in FIG. 20, the heights of the prisms 71 in the first light-extracting layer 7 gradually increase from the middle to the both sides, and the heights of the convex lenses 91 in the second light-extracting layer 9 gradually decrease from the center region to the peripheral region surrounding the center region.

In this way, if the condition that the brightness attenuation of lights with different colors at different view angles is inconsistent occurs (for example, the brightness attenuation of blue light is severe along with increase of the view angle, but the brightness attenuation of red light and green light is small along with increase of the view angle), in order to make the brightness attenuation of lights with different colors at different view angles consistent along with increase of the view angle, the first light-extracting layers 7 may be set on the light-outlet sides of the first color-converting pattern 61 and the second color-converting pattern 62, and the heights of the respective prisms 71 in the first light-extracting layer 7 in the direction perpendicular to the light-emitting base plate 100 are made gradually increase along the direction from the middle region to the edge region. In this way, the prisms 71 may adjust angles of outlet lights of red light and green light, and at the same time, the prisms 71 may, to a certain extent, increase the attenuation of the outlet lights of red light and green light along with increase of the view angle, such that the lights with different colors attenuate consistently along with increase of the view angle, thus releasing the problem of color deviation of large view angle of the display panel. In addition, the heights of the convex lenses 91 in the second light-extracting layer 9 may be set to gradually decrease from the center region to the peripheral region surrounding the center region, which may weaken converging effect of the convex lenses 91 on the light emitted from the edge region, so as to increase brightness of the center view angle of the display panel, and at the same time, to a certain extent, to increase the attenuation of red light and green light along with increase of the view angle, such that the lights with different colors attenuate consistently along with increase of the view angle, thus further releasing the problem of color deviation of large view angle of the display panel.

It should be noted that the embodiments of the present application are illustrated, by taking that the first light-emitting device 31, the second light-emitting device 32 and the third light-emitting device 33 all emit blue light, the first color-converting pattern 61 includes red quantum dots, the second color-converting pattern 62 includes green quantum dots, and the light-transmitting pattern 63 includes transparent resin, as an example.

In some embodiments of the present application, referring to that shown in FIG. 1, the display panel further includes a first cover layer 8 and a second cover layer 10, the first cover layer 8 covers at least the first light-extracting layers 7, and the second cover layer 10 covers the second light-extracting layers 9, wherein a refractive index of the first light-extracting layer 7 is greater than that of the first cover layer 8, and a refractive index of the second light-extracting layer 9 is greater than that of the second cover layer 10.

In an exemplary embodiment, both the refractive index of the first light-extracting layer 7 and the refractive index of the second light-extracting layer 9 range from 1.45 to 1.75.

For example, materials of both the first light-extracting layer 7 and the second light-extracting layer 9 may be an organic material.

For example, the organic material may include at least one of: acrylic resin, epoxy resin and acrylic resin.

For example, the refractive index of the first cover layer 8 and the refractive index of the second cover layer 10 range from 1.2 to 1.7.

For example, thicknesses of the first cover layer 8 and the second cover layer 10 range from 10 μm to 50 μm.

Whether the thicknesses of the first cover layer 8 and the second cover layer 10 are the same, is not limited here, which may be determined according to an actual situation.

In some embodiments of the present application, the refractive index of the first cover layer 8 is greater than that of the second light-extracting layer 9.

In the embodiment of the present application, the refractive index of the first light-extracting layer 7 is set to be greater than the refractive index of the first cover layer 8, and the refractive index of the second light-extracting layer 9 is set to be greater than the refractive index of the second cover layer 10, which may improve efficiency that light emitted from the light-extracting layer emits out of the display panel through the packaging layer, so as to reduce loss of light, to improve the light-outlet intensity of the display panel, thus improving the display effect thereof.

In some embodiments of the present application, the prism 71 is an isosceles prism.

In the embodiments of the present application, the prism 71 is set as the isosceles prism, the prism 71 is made in a mirror symmetrical structure, which may make two light-outlet surfaces of the prism 71 symmetrical, so as to make lights emitted from the two light-outlet surfaces of the prism 71 evenly distributed, thus improving distribution uniformity of the light emitted from the display panel, so as to improve brightness uniformity of the display panel.

The followings take the structure shown in FIG. 1 as an example, to illustrate contrast curves of attenuation of the light-outlet intensity of the display panel provided by an embodiment of the present application and the light-outlet intensity of the display panel in the related technology at different view angles. Among them, the display panel provided by the embodiment of the present application is provided with the first light-extracting layers 7 on the light-outlet sides of the first color-converting pattern 61 and the second color-converting pattern 62, and the second light-extracting layers 9 on the light-outlet sides of the first color-converting pattern 61, the second color-converting pattern 62 and the light-transmitting pattern 63. The first light-emitting device 31, the second light-emitting device 32 and the third light-emitting device 33 are light-emitting layers of blue OLED (Organic Light-Emitting Diode), the first color-converting pattern 61 includes the red quantum dots, the second color-converting pattern 62 includes the green quantum dot layers, the light-transmitting pattern 63 includes the transparent resin, the first color-resistance pattern 121 is a color-resistance pattern of red color, the second color-resistance pattern 122 is a color-resistance pattern of green color, and the third color-resistance pattern 123 is a color-resistance pattern of blue color.

The respective light-emitting devices 3 of the display panel provided by the embodiments of the present application are light-emitting devices of blue light OLED. Referring to luminance-decay curves of lights of different colors at different view angles for a display panel in related technology shown in FIG. 23, attenuation of light intensity of blue light (mark B) is severe at a large view angle, while attenuation of light intensity of red light (mark R) and green light (mark G) is slow at the large view angle, which makes the display panel in the related technology appears partial yellow at the large view angle, in solving a problem that a display screen appears partial yellow at the large view angle, it is necessary to make the brightness attenuation of the lights with three colors at different view angles consistent.

FIG. 21 is a schematic view showing luminance-decay (L-Decay) curves of the display panel provided by the embodiments of the present application, at different view angles, before and after the first light-extracting layers 7 are set on the light-outlet sides of the first color-converting pattern 61 and the second color-converting pattern 62. Among them, a mark Without7&9 indicates that no first light-extracting layer 7 and no second light-extracting layer 9 is set, a mark With7-Direction OB indicates a luminance-decay curve at different view angles in an extending direction of the prisms 71 in the first light-extracting layer 7, and a mark With7-Direction OA indicates a luminance-decay curve at different view angles in an arrangement direction of the prisms 71 in the first light-extracting layer 7. It may be seen from data in FIG. 21 that, in a condition that only the first light-extracting layers 7 are set, the attenuation of light intensity of the display panel increases at the large view angle. However, the plurality of prisms 71 in the first light-extracting layer 7 extend along the first direction OB and are arranged along the second direction OA, which makes the luminance-decay curve along the first direction OB appears to be warped at the large view angle. This shows that only setting the first light-extracting layers 7 may release the problem that a display screen appears partial yellow at the large view angle, to a limited extent.

FIG. 22 is a schematic view showing luminance-decay curves of the display panel provided by the embodiments of the present application, at different view angles, before and after the first light-extracting layers 7 are respectively set on at the light-outlet sides of the first color-converting pattern 61 and the second color-converting pattern 62 and then the second light-extracting layers 9 are respectively set on the light-outlet sides of the first color-converting pattern 61, the second color-converting pattern 62 and the light-transmitting pattern 63. Among them, a mark Without7&9 indicates that no first light-extracting layers and no second light-extracting layer is set. A mark With7&9 indicates that the first light-extracting layers and the second light-extracting layers are set. Apparently, in combination with the luminance-decay curve of blue light shown in FIG. 23, after the first extraction layers 7 are set on the light-outlet sides of the first color-converting pattern 61 and the second color-converting pattern 62, and the second light-extracting layers 9 are set on all of the light-outlet sides of the first color-converting pattern 61, the second color-converting pattern 62, and the light-transmitting pattern 63, the light intensity of the display panel at the center view angle (near)(°) increases, and the attenuation of light intensity of the display panel at the large view angle is consistent with the attenuation curves of the respective blue light.

FIG. 23 is a schematic view showing luminance-decay curves of red light, green light and blue light in the display panel, when no first light-extracting layer 7 and no second light-extracting layer 9 is set. Apparently, attenuation trends of the three lights are inconsistent. FIG. 24 is a schematic view showing luminance-decay curves of red, green and blue light, after setting the first light-extracting layers 7 on the light-outlet sides of the first color-converting pattern 61 and the second color-converting pattern 62, and setting the second light-extracting layers 9 on all of the light-outlet sides of the first color-converting pattern 61, the second color-converting pattern 62 and the light-transmitting pattern 63. Apparently, the attenuation trends of brightness of the three colors are consistent, thus releasing the problem of color deviation occurring in screen of the display panel at different view angles (including large view angles), such that the display effect of display panel may be improved.

FIG. 25 is a schematic view showing a track of white point coordinates of a display panel, changed in a color gamut diagram along with view angles, before setting the first light-extracting layers 7 and the second light-extracting layers 9, and after setting the first light-extracting layers 7 and the second light-extracting layers 9. Among them, a direction indicated by a dotted-line arrow is the track of white point changed along with increase of the view angle, before setting the first light-extracting layers 7 and the second light-extracting layers 9. It may be seen that the white point gradually turns partial yellow with increase of the view angle. A direction indicated by a solid-line arrow is the track of white point changed along with increase of the view angle, after setting the first light-extracting layers 7 and the second light-extracting layers 9. It may be seen, the problem that the white point gradually turns partial yellow with increase of the view angle, is released.

An embodiment of the present application further provides a display device, including the display panel as described above. The display device further includes a drive IC for driving the display panel, and a power supply circuit for supplying power.

The specific structure of the display panel included in the above display device may be referred to the previous description, which will not be repeated here.

In the display device provided by the embodiments of the present application, the first light-extracting layers 7 are set on the light-outlet sides of at least a part of the light-emitting devices 3. The first light-extracting layer 7 includes the plurality of prisms 71 extending along the first direction OB and arranged along the second direction OA. The prisms 71 may refract the light emitted from the light-emitting base plate 100 and adjust the light intensity of the respective sub-pixels in the display panel at different view angles, thus releasing the problem of color deviation of large view angle of the display panel. Then, by setting the second light-extracting layers 9, the second light-extracting layer 9 includes the plurality of convex lenses 91 arranged in the array, and the plurality of convex lenses 91 arranged in the array may cooperate with the plurality of prisms 71. On the one hand, the prisms 71 extend along the first direction OB and are arranged along the second direction OA, which may cause difference in light intensity between the first direction OB and the second direction OA in the display panel, so the convex lenses 91 may release the difference in light intensity between the first direction OB and the second direction OA in the display panel. On the other hand, the structure of the convex lenses 91 may play a good role in converging the light emitted from the first light-extracting layers 7 and the light emitted from the areas between every two adjacent prisms 71 in the first light-extracting layers 7, thus improving light-outlet intensity of the overall display panel and improving display effect thereof. In addition, the maximum size W of the prism 71 along the second direction OA is less than or equal to the maximum size D of the convex lens 91 along the second direction OA, which may make the light passing through the prisms 71 and refracted by the prisms 71 send into the convex lenses 91 as much as possible, thus further improving light-converging function of the convex lenses 91 and thus further improving the light-outlet efficiency thereof.

The display device provided by the embodiments of the present application may further include other structures and components. The said other structures and components included in the display device may be referred to the related technology, which is not limited here.

The above is only the specific implementations of the application, but the scope of protection of the application is not limited thereto. Any technical personnel familiar with the technical field may easily think of changes or replacements within the scope of technology disclosed in the application, which should be covered in the scope of protection of the application. Therefore, the scope of protection of the application shall be subject to the scope of protection of the claims.

1. A display panel, comprising:
a light-emitting base plate, comprising a plurality of light-emitting devices arranged in an array;
first light-extracting layers, located on light-outlet sides of at least a part of the light-emitting devices, wherein each of the first light-extracting layers comprises a plurality of prisms extending along a first direction and arranged along a second direction; and
second light-extracting layers, located on the light-outlet sides of the light-emitting devices, and on a side of the first light-extracting layers away from the light-emitting base plate, wherein each of the second light-extracting layers comprises a plurality of convex lenses arranged in an array,
wherein an orthographic projection of each of the first light-extracting layers on the light-emitting base plate is within an orthographic projection of a corresponding one of the second light-extracting layers on the light-emitting base plate, a maximum size of the prism along the second direction is less than or equal to a maximum size of the convex lens along the second direction, and the first direction intersects the second direction.

2. The display panel according to claim 1, wherein, along the second direction, a spacing size between every two adjacent ones of the prisms is greater than or equal to a spacing size between every two adjacent ones of the convex lenses.

3. The display panel according to claim 1, wherein, for the first light-extracting layer and the second light-extracting layer located on the light-outlet side of a same one of the light-emitting devices, an outer contour of the orthographic projection of the first light-extracting layer on the light-emitting base plate is within an outer contour of the orthographic projection of the second light-extracting layer on the light-emitting base plate.

4. The display panel according to claim 3, wherein, for the first light-extracting layer and the second light-extracting layer located on the light-outlet side of the same one of the light-emitting devices, the outer contour of the orthographic projection of the first light-extracting layer on the light-emitting base plate is within an outer contour of an orthographic projection of a first graph on the light-emitting base plate, and
the first graph is a closed graph formed by successively connecting focuses of the convex lenses of an outermost lap in the second light-extracting layer.

5. The display panel according to claim 4, further comprising: color-resistance layers, wherein the color-resistance layers are located on a side of the second light-extracting layers away from the light-emitting base plate, and
the outer contour of the orthographic projection of the second light-extracting layer on the light-emitting base plate is located within an outer contour of an orthographic projection of the corresponding color-resistance layer on the light-emitting base plate.

6. The display panel according to claim 4, further comprising: color-resistance layers, wherein the color-resistance layers are located on a side of the second light-extracting layers away from the light-emitting base plate, and
the orthographic projection of the second light-extracting layer on the light-emitting base plate partially overlaps with an orthographic projection of the corresponding color-resistance layer on the light-emitting base plate, and the outer contour of the orthographic projection of the first graph on the light-emitting base plate is within an outer contour of the orthographic projection of the color-resistance layer on the light-emitting base plate.

7. The display panel according to claim 1, further comprising: a substrate, color-converting layers, and color-resistance layer, wherein the color-converting layers are located between a part of the light-emitting devices and the first light-extracting layers, and the color-resistance layers are located on a side of the second light-extracting layers away from the light-emitting base plate, and
wherein orthographic projections of the color-converting layers on the substrate cover at least a part of orthographic projections of the light-emitting devices on the substrate, and orthographic projections of the color-resistance layers on the substrate overlap with orthographic projections of the color-converting layer on the substrate.

8. The display panel according to claim 7, wherein the light-emitting devices comprise first light-emitting devices, second light-emitting devices, and third light-emitting devices, the color-converting layers comprise first color-converting patterns on a light-outlet side of the first light-emitting devices and second color-converting patterns on a light-outlet side of the second light-emitting devices, the display panel further comprises light-transmitting patterns located on a light-outlet side of the third light-emitting devices, and the light-transmitting patterns are arranged on a same layer as the color-converting layers, and
wherein, light-emitting colors of the first light-emitting device, the second light-emitting device and the third light-emitting device are the same, and color of light converted by the first color-converting pattern, color of light converted by the second color-converting pattern and color of light passing the light-transmitting pattern are different from each other.

9. The display panel according to claim 8, wherein the first color-converting pattern and the second color-converting pattern respectively comprise quantum dots, and the light-transmitting pattern comprises scattering particles.

10. The display panel according to claim 1, wherein orthographic projections of a row of the convex lenses on the light-emitting base plate overlap with an orthographic projection of at least one of the prisms on the light-emitting base plate.

11. The display panel according to claim 10, wherein, along the second direction, a number of the prisms comprised in the first light-extracting layer is greater than or equal to a number of the convex lenses comprised in the second light-extracting layer.

12. The display panel according to claim 11, wherein the first light-extracting layer comprises first prisms and second prisms that are spaced, and
maximum sizes of the first prism and the second prism along the second direction are the same, and a height of the first prism in a direction perpendicular to the light-emitting base plate is greater than or equal to a height of the second prism in the direction perpendicular to the light-emitting base plate.

13. The display panel according to claim 12, wherein the second light-extracting layer comprises first convex lenses and second convex lenses that are spaced along the second direction, and
maximum sizes of the first convex lens and the second convex lens along the second direction are the same, and a height of the first convex lens in the direction perpendicular to the light-emitting base plate is greater than or equal to a height of the second convex lens in the direction perpendicular to the light-emitting base plate.

14. The display panel according to claim 13, wherein, along the second direction, the number of prisms comprised in the first light-extracting layer is equal to the number of convex lenses comprised in the second light-extracting layer, and
an orthographic projection of the first convex lens on the light-emitting base plate overlaps with an orthographic projection of the first prism on the light-emitting base plate, and an orthographic projection of the second convex lens on the light-emitting base plate overlaps with an orthographic projection of the second prism on the light-emitting base plate.

15. The display panel according to claim 11, wherein, along the second direction, the number of prisms comprised in the first light-extracting layer is greater than the number of convex lenses comprised in the second light-extracting layer.

16. The display panel according to claim 15, wherein the orthographic projections of the row of convex lenses on the light-emitting base plate overlap with the orthographic projections of two of the prisms on the light-emitting base plate, and an orthographic projection of a connecting line of focus of the row of convex lenses on the light-emitting base plate is located between the orthographic projections of the two of prisms on the light-emitting base plate.

17. The display panel according to claim 1, wherein the first light-extracting layer comprises a middle region and an edge region on both sides of the middle region, wherein heights of the respective prisms in the first light-extracting layer in a direction perpendicular to the light-emitting base plate gradually decrease along a third direction, and
the third direction is a direction from the edge region to the middle region, or the third direction is a direction from the middle region to the edge region.

18. The display panel according to claim 1, wherein the second light-extracting layer comprises a center region and a peripheral region surrounding the center region, wherein heights of the respective convex lenses in the second light-extracting layer in a direction perpendicular to the light-emitting base plate gradually decrease along a fourth direction, and
the fourth direction is a direction from the peripheral region to the center region, or the fourth direction is a direction from the center region to the peripheral region.

19. The display panel according to claim 1, wherein
the first light-extracting layer comprises a middle region and an edge region on both sides of the middle region, wherein heights of the respective prisms in the first light-extracting layer in a direction perpendicular to the light-emitting base plate gradually decrease along a direction from the middle region to the edge region, and
the second light-extracting layer comprises a center region and a peripheral region surrounding the center region, wherein heights of the respective convex lenses in the second light-extracting layer in a direction perpendicular to the light-emitting base plate gradually increase along a direction from the center region to the peripheral region.

20-21. (canceled)

22. A display device, comprising the display panel according to claim 1.
